(19) United States
(12) Patent Application Publication
(10) Pub. No.: US 2026/0231454 A1
(43) Pub. Date: Aug. 6, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: Cheng-Yu WEI, Taoyuan City (TW); Cheng-I LIN, Hsinchu (TW); Shu-Han CHEN, Hsinchu City (TW); Jyun-Yi WU, Hsinchu (TW); Chi On CHUI, Hsinchu City (TW)

(21) Appl. No.: 19/044,399

(22) Filed: Feb. 3, 2025

(51) Int. Cl. H10D 30/01; H01L 21/02; H10D 30/00; H10D 64/66

(52) U.S. Cl. CPC H10D 30/0196; H10D 30/508; H10P 14/6339; H10D 64/675; H10P 14/668

(57) ABSTRACT

Flowable low-k and ultra low-k dielectric materials may be used as materials for inner spacers to prevent formation of inner spacer defects. A flowable deposition process (e.g., a flowable chemical vapor deposition (FCVD) process) may be used to deposit the flowable low-k and ultra low-k dielectric materials to avoid inner spacer defect formation. Ratios of precursors to reactants used in the flowable deposition process may be tuned to increase flowability to prevent generation of seams and/or voids in the inner spacers. If defect formation is avoided, processes to trim and/or clean nanostructure channel surfaces prior to epitaxial growth of source/drain regions may be performed for a requisite amount of time without concern that defects will be enlarged. Due to the lack of defects in inner spacers formed using the techniques described herein, the inner spacers may provide increased protection from parasitic capacitance between gates and source/drain regions in nanostructure transistors.

### BACKGROUND

As semiconductor device manufacturing advances and technology processing nodes decrease in size, transistors may become affected by short channel effects (SCEs) such as hot carrier degradation, barrier lowering, and quantum confinement, among other examples. In addition, as the gate length of a transistor is reduced for smaller technology nodes, source/drain (S/D) electron tunneling increases, which increases the off current for the transistor (the current that flows through the channel of the transistor when the transistor is in an off configuration).

Silicon (Si)/silicon germanium (SiGe) nanostructure transistors such as nanowires, nanosheets, and gate-all-around (GAA) devices are potential candidates to overcome short channel effects at smaller technology nodes. Nanostructure transistors are efficient structures that may experience reduced SCEs and enhanced carrier mobility relative to other types of transistors.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1C are diagrams of an example implementation of a fin definition process described herein.

FIG. 2 is a diagram of an example dummy gate structure formation process described herein.

FIG. 3 is a diagram of an example implementation of a source/drain recess formation process described herein.

FIGS. 4A-4C are diagrams of an example implementation of an inner spacer formation process described herein.

FIG. 5 is a diagram of an example implementation of a source/drain region formation process described herein.

FIG. 6 is a diagram of an example implementation of an interlayer dielectric formation process described herein.

FIGS. 7A-7C are diagrams of an example implementation of a replacement gate process described herein.

FIGS. 8A-8F are diagrams of an example implementation of manufacturing a semiconductor device described herein.

FIGS. 9 and 10 are flowcharts of example processes associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A nanostructure transistor may include a gate structure that wraps around a plurality of nanostructure channels. The gate structure wrapping around the nanostructure channels increases control of the gate structure over a conductive channel in the nanostructure channels, increases drive current for the nanostructure transistor, and/or may reduce short channel effects (SCEs) for the nanostructure transistor, among other examples. In some cases, a semiconductor device may include p-type metal oxide semiconductor (PMOS) nanostructure transistors and n-type metal oxide semiconductor (NMOS) nanostructure transistors. Integrating PMOS nanostructure transistors and NMOS nanostructure transistors into the same semiconductor device enables complementary metal oxide semiconductor (CMOS) integrated circuits to be realized in the semiconductor device. CMOS integrated circuits have many use cases in the semiconductor industry, including microprocessors (e.g., central processing units (CPUs)), graphics processing units (GPUs)), memory devices, digital logic circuitry, image sensors (e.g., CMOS image sensors), and/or radio frequency (RF) circuitry, among other examples.

However, nanostructure transistors face fabrication challenges that can cause performance issues, manufacturing yield issues, and/or device failures. For example, in an effort to reduce or prevent parasitic capacitance between gates and source/drain regions in nanostructure transistors, dielectric inner spacers may be formed between gates and source/drain regions in stacked nanosheet structures to block charge from reaching the source/drain regions. The inner spacers may also protect source/drain regions from being damaged in a nanosheet release operation to remove sacrificial nanostructure layers between nanostructure channels and replace the sacrificial nanostructure layers with gate structures. In some cases, techniques used to form the inner spacers may result in defects in the inner spacers. The defects, which include seams and/or voids in the inner spacers, limit the ability of the inner spacers to reduce or prevent parasitic capacitance and/or to protect the source/drain regions from damage. In more detail, as integrated circuits and inner spacer area decrease in size, some deposition techniques used to form the inner spacers, such as thermal atomic layer deposition (ALD), plasma-enhanced ALD (PEALD), and plasma-enhanced chemical vapor deposition (PECVD), may result in the generation of voids and/or seams in the inner spacers. As a result, current from gates may leak through the seams and/or voids, thereby increasing parasitic capacitance between gates and source/drain regions. The presence of the defects may also allow etchants used during removal of sacrificial nanostructure layers to contact and damage source/drain regions. In addition, metal that is deposited in place of the sacrificial nanostructure layers to form gate structures may contact and damage source/drain regions through the seams and/or voids, thereby reducing performance of the source/drain regions.

Further, subsequent trimming and/or cleaning processes to remove excess spacer material layers performed after deposition may enlarge inner spacer defects. As a result, trimming or cleaning processes may be shortened to avoid defect enlargement. Less time to perform trimming or cleaning processes can result in nanostructure channel surfaces from, and/or on, which epitaxial growth is to occur including unwanted inner spacer material, which may lead to a reduction in the area and/or quality of epitaxial source/drain regions.

In some implementations described herein, flowable low dielectric constant (low-k) and ultra low-k dielectric materials may be used as materials for nanostructure transistor inner spacers to prevent the formation of inner spacer defects. A flowable deposition process (e.g., a flowable chemical vapor deposition (FCVD) process) may be used to deposit the flowable low-k and ultra low-k dielectric materials (e.g., aluminum oxide (AlOₓ), silicon carbide (SiCₓ), silicon oxycarbonnitride (SiOₓC_{y}N_{1-x-y}), silicon nitride (SiNₓ)) to avoid inner spacer defect formation. Ratios of precursors to reactants used in the flowable deposition process may be tuned to increase flowability to prevent generation of seams and/or voids in the inner spacers.

If defect formation is avoided, processes to trim and/or clean nanostructure channel surfaces prior to epitaxial growth of source/drain regions may be performed for a requisite amount of time without concern that defects will be enlarged. As a result, inner spacer material may be sufficiently removed from the surfaces from, and/or on, which source/drain regions will be formed, leading to larger areas of higher quality and uncontaminated epitaxial source/drain regions. Moreover, due to the lack of defects in inner spacers formed using the techniques described herein, the inner spacers may provide increased protection from parasitic capacitance between gates and source/drain regions in nanostructure transistors. The void-and/or seam-free inner spacers may also prevent etchants and/or deposited metal from a replacement metal gate operation from contacting and/or damaging source/drain regions, thereby increasing performance and yield of resulting nanostructure transistors, in comparison to when other spacer materials and deposition processes are used.

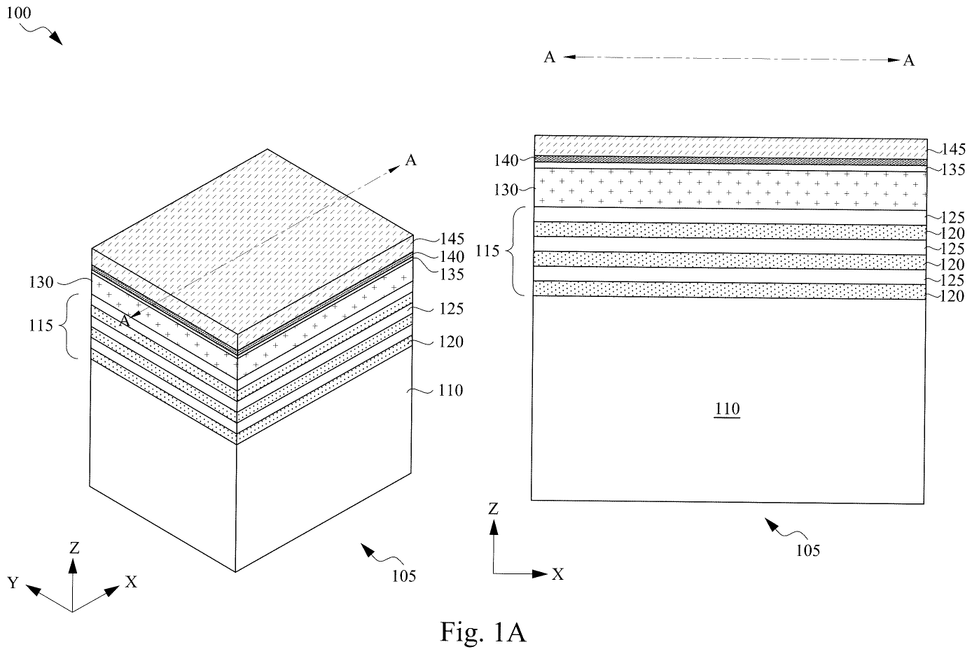

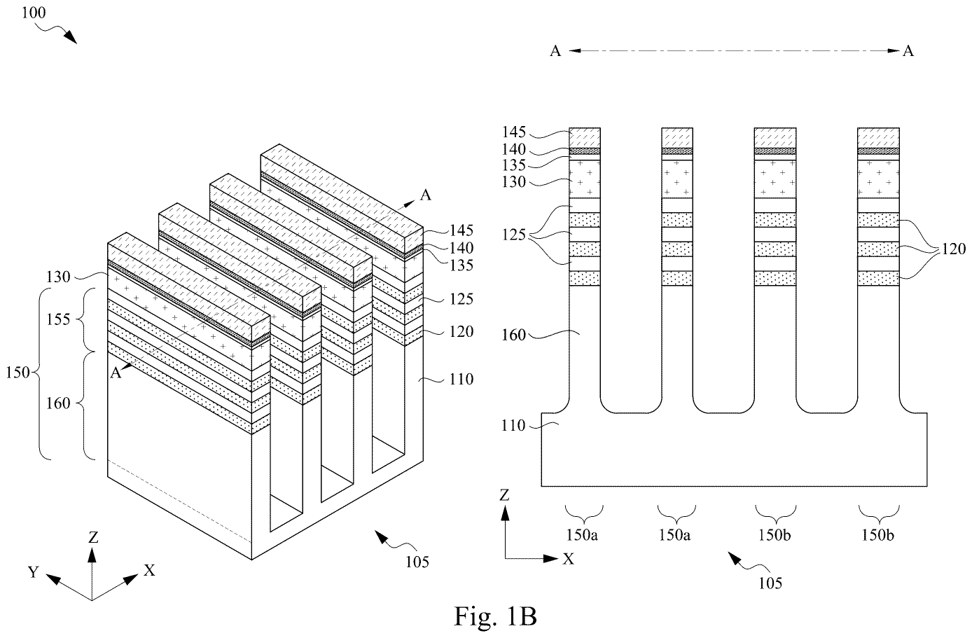

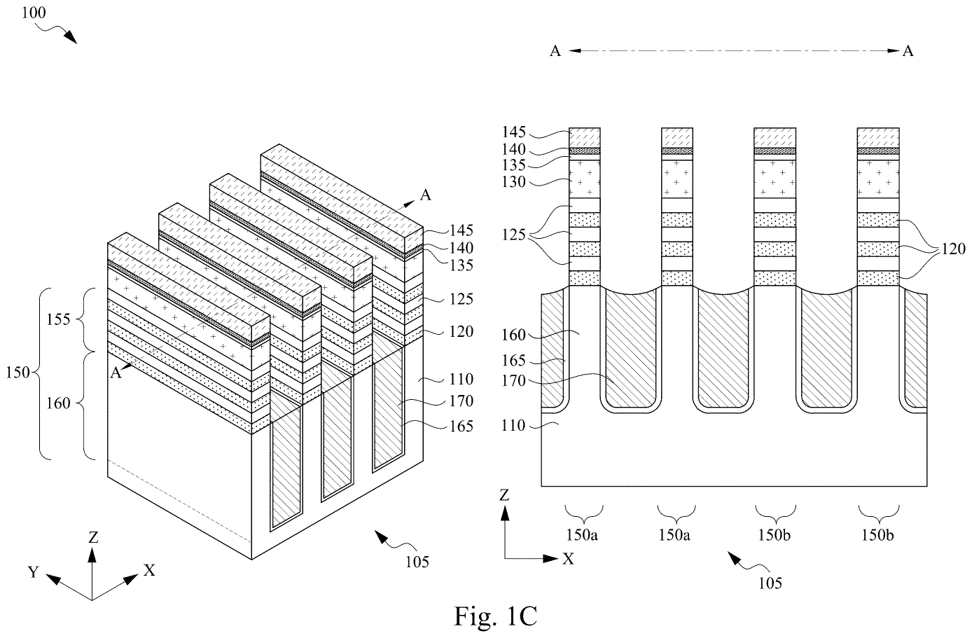

FIGS. 1A-1C are diagrams of an example implementation 100 of a fin definition process described herein. The example implementation 100 includes an example of forming fin structures and associated shallow trench isolation (STI) regions for a semiconductor device 105 described herein. The semiconductor device 105 may be manufactured to include one or more transistors. The one or more transistors may include nanostructure transistor(s) such as nanowire transistors, nanosheet transistors, gate-all-around (GAA) transistors, multi-bridge channel transistors, nanoribbon transistors, and/or other types of nanostructure transistors. The example implementation 100 includes an example of forming the fin structures and the associated STI regions for the transistors of the semiconductor device 105.

FIGS. 1A-1C each illustrate a perspective view of the semiconductor device 105 and a cross-sectional view along the line A-A in the perspective view. As shown in FIG. 1A, processing of the semiconductor device 105 is performed in connection with a semiconductor substrate 110. The semiconductor substrate 110 includes a silicon (Si) substrate, a substrate formed of a material including silicon, a III-V compound semiconductor material substrate such as gallium arsenide (GaAs), a silicon on insulator (SOI) substrate, a germanium (Ge) substrate, a silicon germanium (SiGe) substrate, a silicon carbide (SiC) substrate, or another type of semiconductor substrate.

A layer stack 115 is formed on the semiconductor substrate 110. The layer stack 115 may be referred to as a superlattice. The layer stack 115 includes a plurality of alternating layers that are arranged in a direction (e.g., the z-direction) that is approximately perpendicular to the semiconductor substrate 110. For example, the layer stack 115 includes vertically alternating layers of sacrificial nanostructure layers 120 and nanostructure channel layers 125 above the semiconductor substrate 110. The quantity of the sacrificial nanostructure layers 120 and the quantity of the nanostructure channel layers 125 illustrated in FIG. 1A are examples, and other quantities of the sacrificial nanostructure layers 120 and the nanostructure channel layers 125 are within the scope of the present disclosure.

The sacrificial nanostructure layers 120 enable a vertical distance to be defined between adjacent nanostructure channels that are formed from the nanostructure channel layers 125, and serve as placeholder layers for subsequently-formed gate structures of the transistors of the semiconductor device 105 that are formed around the nanostructure channels. The sacrificial nanostructure layers 120 include a first material composition, and the nanostructure channel layers 125 include a second material composition. In some implementations, the first material composition and the second material composition are the same material composition. In some implementations, the first material composition and the second material composition are different material compositions. As an example, the sacrificial nanostructure layers 120 may include silicon germanium (SiGe) and the nanostructure channel layers 125 may include silicon (Si). This enables the sacrificial nanostructure layers 120 and/or the nanostructure channel layers 125 to be selectively etched (e.g., enables the sacrificial nanostructure layers 120 and not the nanostructure channel layers 125 to be etched, enables the nanostructure channel layers 125 and not the sacrificial nanostructure layers 120 to be etched) depending on the type of etchant that is used.

One or more types of deposition tools may be used to deposit and/or grow the alternating layers of the layer stack 115 to include nanostructures (e.g., nanosheets) on the semiconductor substrate 110. For example, a deposition tool may be used to grow the sacrificial nanostructure layers 120 and/or the nanostructure channel layers 125 by epitaxial growth, which may include epitaxy techniques such as a molecular beam epitaxy (MBE), metalorganic chemical vapor deposition (MOCVD) process, and/or another suitable epitaxy technique. Additionally and/or alternatively, the sacrificial nanostructure layers 120 and/or the nanostructure channel layers 125 may be deposited by chemical vapor deposition (CVD), physical vapor deposition (PVD), atomic layer deposition (ALD), and/or another suitable deposition technique.

One or more masking layers may be form (e.g., using one or more deposition tools) on the layer stack 115. The masking layer(s) may include a hard mask (HM) layer 130, a capping layer 135, an oxide layer 140, and/or a nitride layer 145. Masking layer(s) may be used to perform a fin patterning operation to form fin structures in the semiconductor substrate 110.

As shown in FIG. 1B, the layer stack 115 and the semiconductor substrate 110 are etched to remove portions of the layer stack 115 and portions of the semiconductor substrate 110. This results in formation of fin structures 150 that extend above the semiconductor substrate 110. The fin structures 150 may extend in a y-direction in the semiconductor device 105 and may be arranged in an x-direction in the semiconductor device 105. A fin structure 150 includes a portion 155 of the layer stack 115 over and/or on a fin portion 160 above the semiconductor substrate 110. The fin structures 150 may be formed by patterning the one or more masking layers and etching the semiconductor substrate 110 based on a pattern formed in one or more of the masking layers. The one or more masking layers may be patterned using photolithography techniques, including double-patterning or multi-patterning techniques. An etch tool may be used to etch the semiconductor substrate 110 based on the pattern using a dry etch technique (e.g., reactive ion etching), a wet etch technique, and/or a combination thereof.

As further shown in FIG. 1B, some fin structures 150 may be formed to have different widths for different types of nanostructure transistors. As an example, a first subset of fin structures 150a may be formed for p-type nanostructure transistors (e.g., p-type metal oxide semiconductor (PMOS) nanostructure transistors), and a second subset of fin structures 150b may be formed for n-type nanostructure transistors (e.g., n-type metal oxide semiconductor (NMOS) nanostructure transistors). As another example, a first subset of fin structures 150a may be formed for nanostructure transistors that are configured to operate at lower voltages, and a second subset of fin structures 150b may be formed for nanostructure transistors that are configured to operate at higher voltages.

As shown in FIG. 1C, a liner 165 and STI regions 170 are formed between adjacent fin portions 160 of the fin structures 150. The liner 165 and the STI regions 170 may each include a dielectric material such as a silicon oxide (SiOₓ), a silicon nitride (SiₓN_{y}), a silicon oxynitride (SiON), fluoride-doped silicate glass (FSG), a low-k dielectric material, and/or another suitable insulating material.

A deposition tool may be used to conformally deposit the liner (e.g., using ALD or another conformal deposition technique), and may deposit a dielectric layer (e.g., using CVD, PVD, a ALD, and/or another suitable deposition technique) on the liner 165 such that the dielectric layer fully fills in the spaces between the fin structures 150 and extends above the tops of the fin structures 150. A planarization tool may then be used to perform a planarization or polishing operation (e.g., a chemical mechanical planarization (CMP) operation) to planarize the dielectric layer such that the top surface of the dielectric layer is approximately co-planar with the top of the nitride layer 145. The nitride layer 145 functions as a CMP stop layer in the planarization operation. An etch tool may be used to then etch the dielectric layer to form the STI regions 170 such that the top surfaces of the STI region 170 are approximately co-planar with or below the bottom-most sacrificial nanostructure layer 120.

As indicated above, FIGS. 1A-1C are provided as an example. Other examples may differ from what is described with regard to FIGS. 1A-1C.

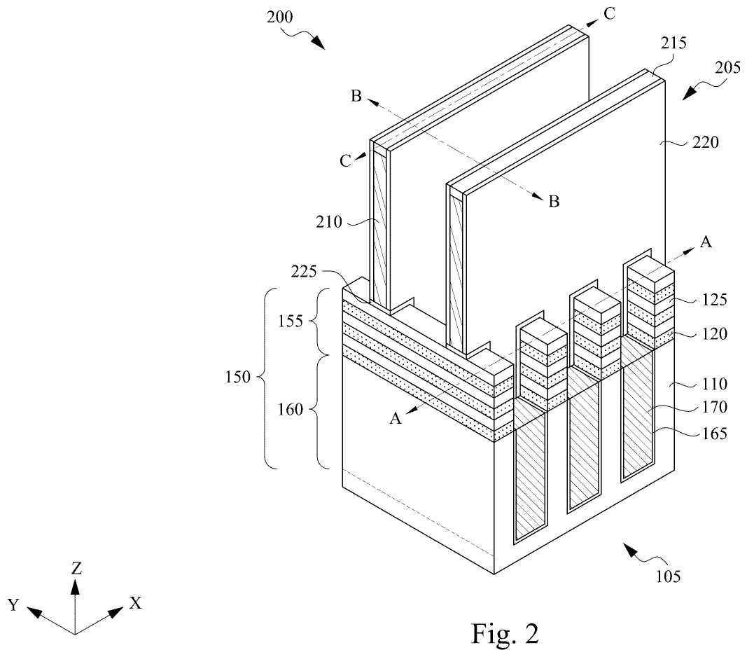

FIG. 2 is a diagram of an example implementation 200 of a dummy gate formation process described herein. The example implementation 200 includes an example of forming dummy gate structures 205 for nanostructure transistors of the semiconductor device 105. In some implementations, the operations described in connection with the example implementation 200 are performed after the processes described in connection with FIGS. 1A-1C.

FIG. 2 illustrates a perspective view of the semiconductor device 105 with the dummy gate structures 205 formed thereon. The dummy gate structures 205 (also referred to as dummy gate stacks or temporary gate structures) are formed over portions of the fin structures 150 and portions of the STI regions 170. The dummy gate structures 205 extend in the x-direction and are arranged in the y-direction such that the dummy gate structures 205 are approximately perpendicular to the fin structures 150. The dummy gate structures 205 are sacrificial structures that are to be replaced by replacement gate structures or replacement gate stacks at a subsequent processing stage for the semiconductor device 105. The dummy gate structures 205 may also be used to define source/drain (S/D) recesses in which source/drain regions of the nanostructure transistors are formed in the fin structures 150.

A dummy gate structure 205 may include a gate electrode layer 210, a hard mask layer 215 over and/or on the gate electrode layer 210, and spacer layers 220 on opposing sides of the gate electrode layer 210, and a gate dielectric layer 225 under the gate electrode layer 210. The gate electrode layer 210 includes polycrystalline silicon (polysilicon or PO) or another material. The hard mask layer 215 includes one or more layers such as an oxide layer (e.g., a pad oxide layer that may include silicon dioxide (SiO₂) or another material) and a nitride layer (e.g., a pad nitride layer that may include a silicon nitride such as Si₃N₄ or another material) formed over the oxide layer. The spacer layers 220 include a silicon oxycarbide (SiOC), a nitrogen free SiOC, or another suitable material. The gate dielectric layer 225 may include a silicon oxide (e.g., SiOₓ such as SiO₂), a silicon nitride (e.g., SiₓN_{y} such as Si₃N₄), a high dielectric constant (high-k) dielectric material (e.g., a dielectric material having a dielectric constant greater than approximately 3.9) and/or another suitable material.

The layers of the dummy gate structures 205 may be formed using various semiconductor processing techniques such depositing the layers of the dummy gate structures 205, patterning the layers of the dummy gate structures 205 to define the dummy gate structures 205, and/or other semiconductor processing techniques.

FIG. 2 further illustrates reference cross-sections that are used in subsequent figures described herein. Cross-section A-A is in an x-z plane (referred to as a y-cut) across the fin structures 150 in the source/drain areas of the semiconductor device 105. Cross-section B-B is in a y-z plane (referred to as an x-cut) perpendicular to the cross-section A-A, and is across the dummy gate structures 205 and along an underlying fin structure 150. Cross-section C-C is in the x-z plane parallel to the cross-section A-A and perpendicular to the cross-section B-B, and is along a dummy gate structure 205. Subsequent figures refer to these reference cross-sections for clarity. In some figures, some reference numbers of components or features illustrated therein may be omitted to avoid obscuring other components or features for ease of depicting the figures.

As indicated above, FIG. 2 is provided as an example. Other examples may differ from what is described with regard to FIG. 2.

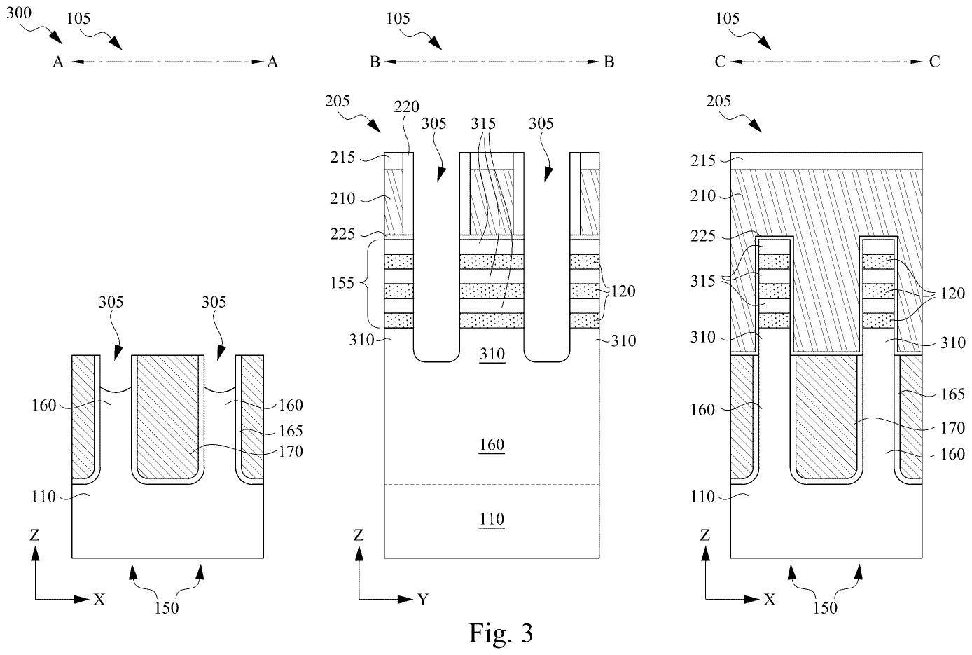

FIG. 3 is a diagrams of an example implementation 300 of a source/drain recess formation process described herein. The example implementation 300 includes an example of forming source/drain recesses 305 for source/drain regions of nanostructure transistors of the semiconductor device 105. FIG. 3 is illustrated from a plurality of perspectives illustrated in FIG. 2, including the perspective of the cross-sectional plane A-A in FIG. 2, the perspective of the cross-sectional plane B-B in FIG. 2, and the perspective of the cross-sectional plane C-C in FIG. 2. In some implementations, the operations described in connection with the example implementation 300 are performed after the processes described in connection with FIGS. 1A-2.

As shown in the cross-sectional plane A-A and cross-sectional plane B-B in FIG. 3, the source/drain recesses 305 are formed through layer stack portions 155 of a fin structure 150 in an etch operation. The source/drain recesses 305 are formed on opposing sides of a dummy gate structure 205. The etch operation may be performed using the etch tool and may be referred to a strained source/drain (SSD) etch operation. In some implementations, the etch operation includes the use of a plasma etch technique, a wet chemical etch technique, and/or another type of etch technique.

The source/drain recesses 305 also extend into a portion of the fin portion 160 of the fin structure 150. This results in formation of mesa regions 310 in the fin structure 150. The sidewalls of the portions of each source/drain recess 305 below the layer stack portions 155 of the fin structure 150 correspond to sidewalls of mesa regions 310. A mesa region 310 (also referred to as pedestals) refers to a region of the fin portion 160 of the fin structure 150 on which nanostructure channels are defined from the nanostructure channel layers 125. The nanostructure channels 315 extend between adjacent source/drain recesses 305 and are located under the dummy gate structure 205 between the adjacent source/drain recesses 305.

The nanostructure channels 315 include silicon-based nanostructures (e.g., nanosheets or nanowires, among other examples) that function as the semiconductive channels of the nanostructure transistors of the semiconductor device 105. In some implementations, the nanostructure channels 315 may include silicon germanium (SiGe) or another silicon-based material. The nanostructure channels 315 are arranged in a direction (e.g., the z-direction) that is approximately perpendicular to the semiconductor substrate 110. In other words, the nanostructure channels 315 are vertically arranged or stacked above the semiconductor substrate 110.

As indicated above, FIG. 3 is provided as an example. Other examples may differ from what is described with regard to FIG. 3.

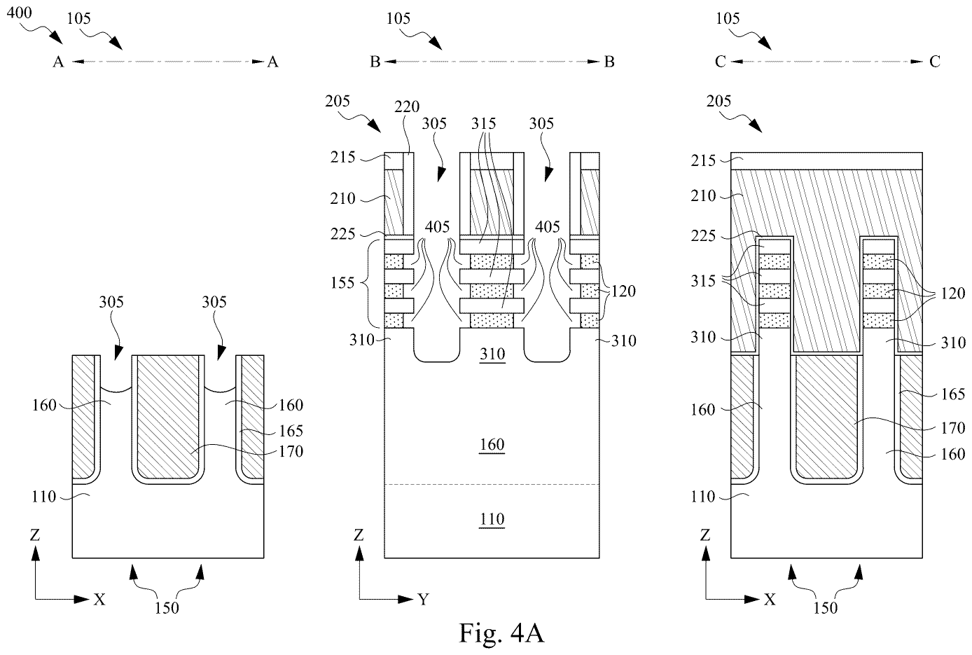

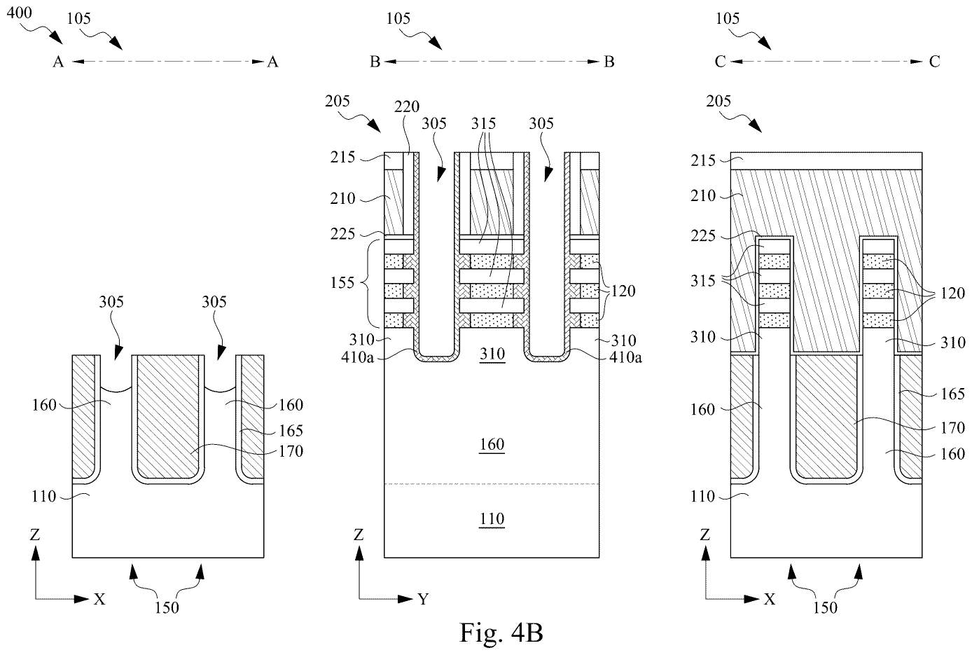

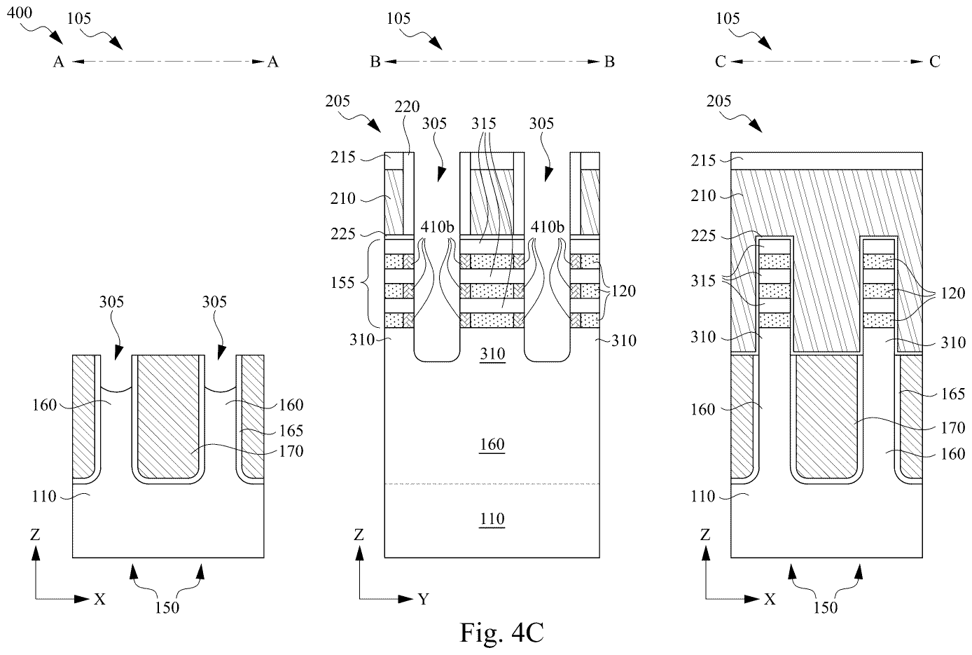

FIGS. 4A-4C are diagrams of an example implementation 400 of an inner spacer formation process described herein. The example implementation 400 includes an example of forming inner spacers between ends of the nanostructure channels 315 that are exposed in the source/drain recesses 305. FIGS. 4A-4C are each illustrated from a plurality of perspectives illustrated in FIG. 2, including the perspective of the cross-sectional plane A-A in FIG. 2, the perspective of the cross-sectional plane B-B in FIG. 2, and the perspective of the cross-sectional plane C-C in FIG. 2. In some implementations, the operations described in connection with the example implementation 400 are performed after the processes described in connection with FIGS. 1A-3.

As shown in the cross-sectional plane B-B in FIG. 4A, the ends of the sacrificial nanostructure layers 120 that are exposed in the source/drain recesses 305 are laterally etched (e.g., in the x-direction that is approximately parallel to a length of the sacrificial nanostructure layers 120) in an etch operation, thereby forming cavities 405 between the ends of the sacrificial nanostructure layers 120 that are exposed in the source/drain recesses 305. In particular, an etch tool may be used to laterally etch the ends of the sacrificial nanostructure layers 120 under the dummy gate structures 205 through the source/drain recesses 305 to form the cavities 405 between ends of the nanostructure channels 315. The cavities 405 may be formed to an approximately curved shape, an approximately concave shape, an approximately triangular shape, an approximately square shape, or to another shape.

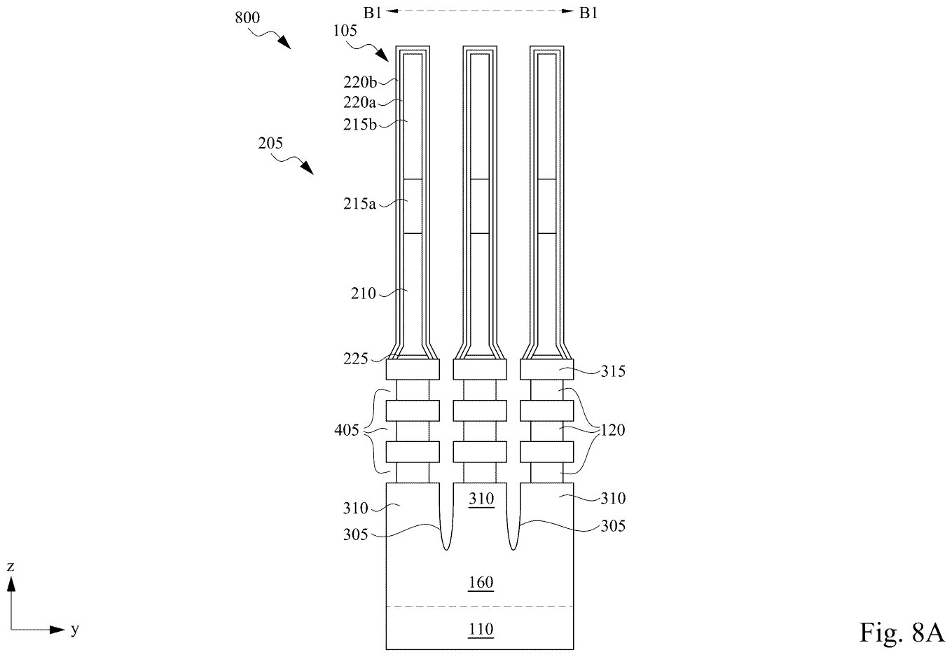

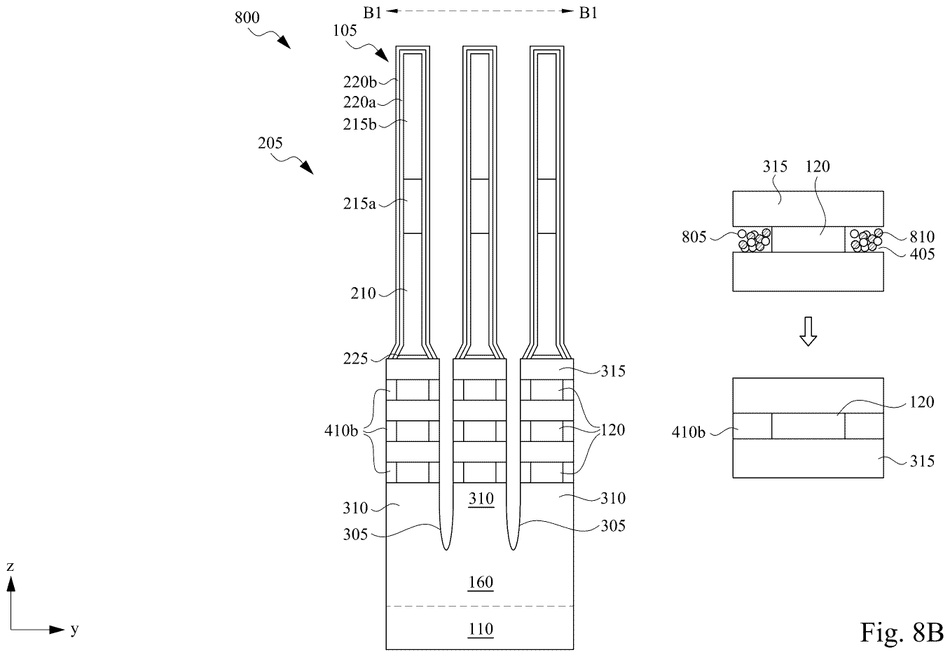

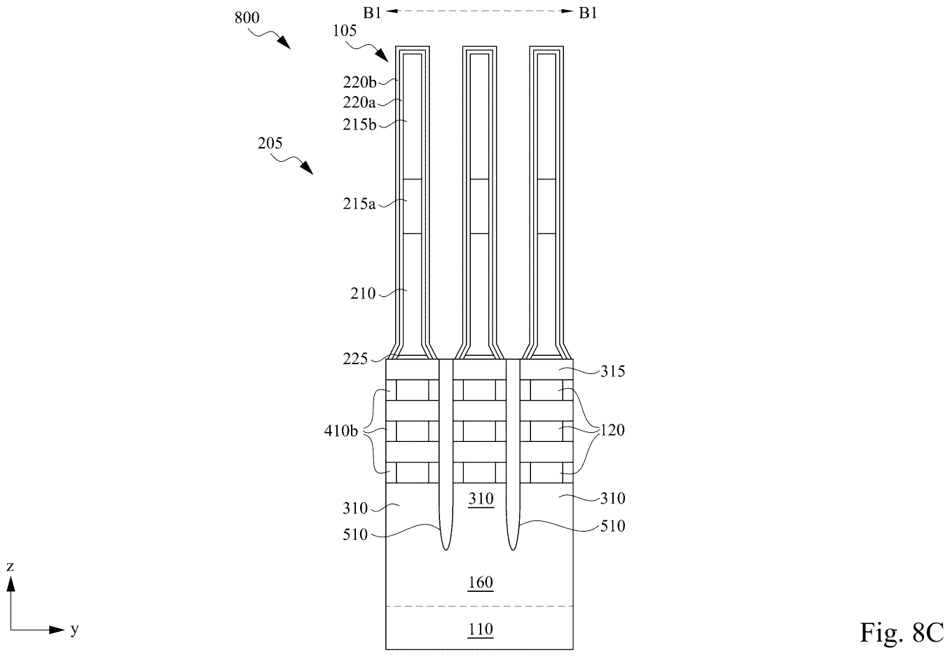

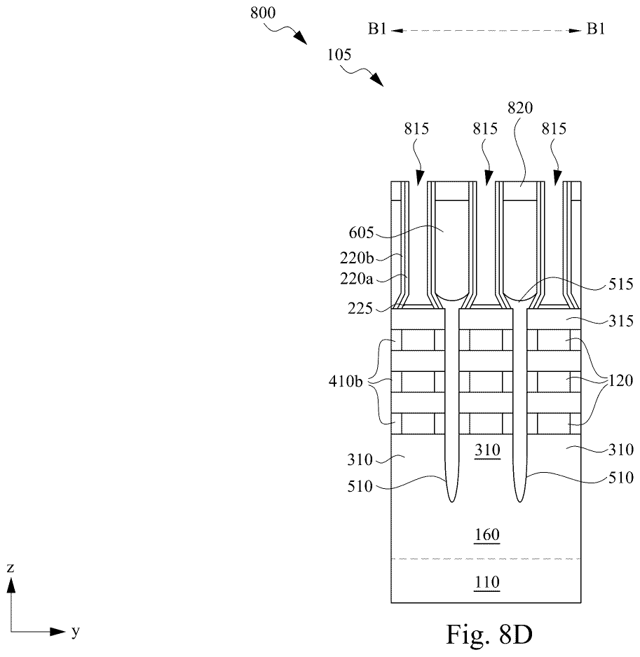

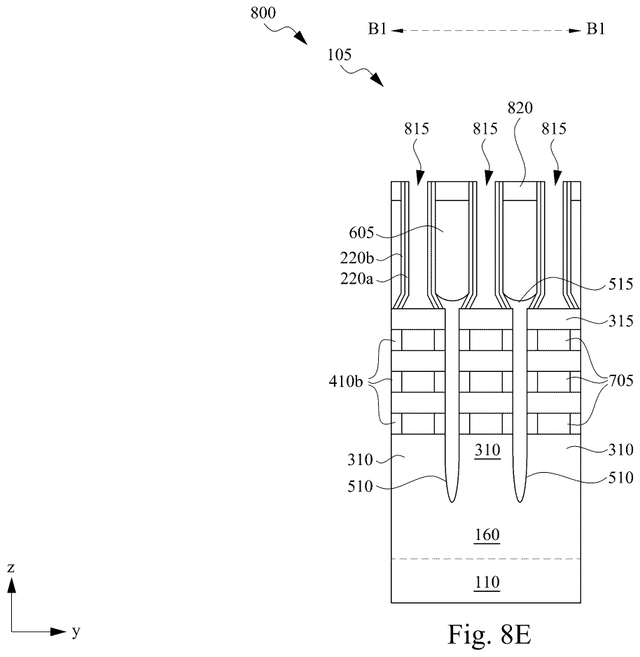

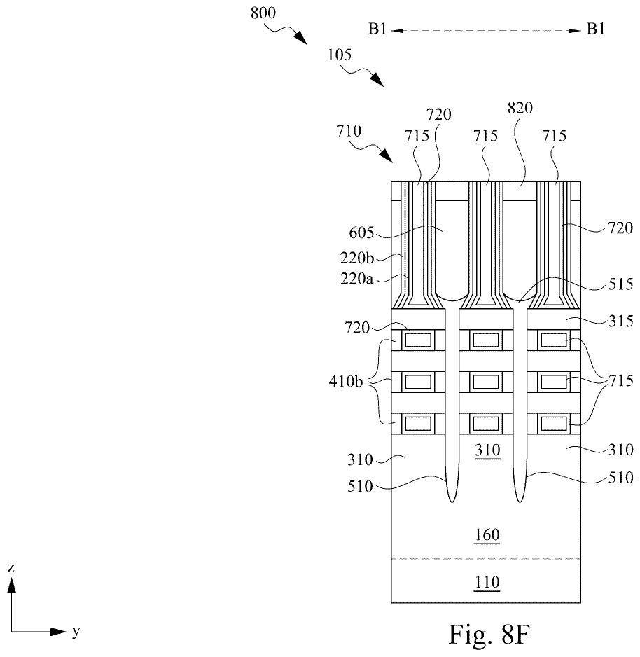

As shown in the cross-sectional plane B-B in FIG. 4B, a deposition tool may be used to deposit an inner spacer layer 410a of dielectric material in the cavities 405 and along the sidewalls and bottom surfaces of the source/drain recesses. A flowable deposition technique (e.g., an FCVD technique) may be used to deposit the inner spacer layer 410a. As explained in more detail herein in connection with FIG. 8B, the flowable deposition technique includes reacting a precursor material with a reactant to form the inner spacer layer 410a. To ensure that material of the inner spacer layer 410a fully fills in the cavities 405 between and around the nanostructure channels 315 and adjacent to remaining portions of the sacrificial nanostructure layers 120, a flowable deposition technique is used to deposit the material of the inner spacer layer 410a. In the flowable deposition technique, a precursor and a reactant flow into the cavities 405 and around the nanostructure channels 315. The precursor and reactant react to form the material of the inner spacer layer 410a. The precursor and the reactant are easily able to flow into the cavities between the nanostructure channels 315, and react to form a material that exhibits high conformal coating and gap filling properties. This enables the material of the inner spacer layer 410a to fully fill in the cavities 405 better than other deposition techniques such as ALD.

To deposit the material of the inner spacer layer 410a, the flowable deposition technique may be used to perform a deposition operation, in which a deposition tool is used to flow the precursor and the reactant into the cavities 405 between the nanostructure channels 315. The semiconductor device 105 may be placed in a processing chamber of the deposition tool (e.g., a flowable CVD tool), and the deposition tool may be used to provide a gas flow containing the precursor, and a gas flow containing the reactant, into the processing chamber. As explained in more detail in connection with FIG. 8B, a ratio of the precursor material to the reactant by volume may be adjusted to control a flowability of the inner spacer layer 410a so that a flowability is achieved that results in the inner spacer layer fully filling in the cavities 405, such that the inner spacer layer 410a is fully merged (e.g., seam-free and/or void-free) between nanostructure channels 315 over and/or under the cavities 405 and ends of sacrificial nanostructure layers 120 on sides of the cavities 405. In some implementations, during the deposition process, the inner spacer layer 410a continues to grow as the material of the inner spacer layer 410a is deposited. The inner spacer layer 410a grows to a sufficient thickness to merge between vertically adjacent nanostructure channels 315.

In some implementations, the inner spacer layer 410a includes a low dielectric constant (low-k) dielectric material (e.g., a dielectric material having a dielectric constant less than approximately 3.9) or an ultra low-k dielectric material (e.g., a dielectric material having a dielectric constant less than approximately 2.4). A low-k value or an ultra low-k value for the material of the inner spacer layer 410a results in reduced parasitic capacitance. Since capacitance is proportional to k-value, low-k and ultra low-k materials reduce parasitic capacitance and improve device performance. In some implementations, the inner spacer layer 410a includes an aluminum oxide (e.g., AlOₓ), a silicon carbide (e.g., SiCₓ), a silicon oxycarbonnitride (e.g., SiOₓC_{y}N_{1-x-y}), and/or a silicon nitride (e.g., SiNₓ).

As shown in the cross-sectional plane B-B in FIG. 4C, in an etching or trimming operation, an etch tool is used to subsequently remove excess material of the inner spacer layer 410a from the source/drain recesses 305 such that remaining portions of the inner spacer layer 410a correspond to the inner spacers 410b in the cavities 405. In some implementations, the surfaces of the inner spacers (InSP) 410b facing the source/drain recesses 305 are approximately flat, such that the surfaces of the inner spacers 410b and the surfaces of the ends of the nanostructure channels 315 are approximately even and flush. In addition to or as an alternative to the etching, the surfaces of the source/drain recesses 305 may be cleaned in a cleaning process to remove any excess material of the inner spacer layer 410a from the source/drain recesses 305 prior to epitaxial growth and/or deposition of source/drain regions in the source/drain recesses 305. The surfaces of the source/drain recesses 305 include exposed surfaces of the nanostructure channels 315 and of the mesa regions 310 from which source/drain regions may be epitaxially grown and/or on which source/regions may be deposited. The cleaning process, which may be performed with, for example, dilute hydrofluoric acid (HF), prepares the exposed surfaces of the source/drain recesses 305 for epitaxial growth and/or deposition of source/drain regions. Since the flowable deposition process may ensure the absence of voids and/or seams in the inner spacers 410b, the subsequent etching and/or cleaning of the excess material of the inner spacer layer 410a is able to be performed for a requisite amount of time to fully or substantially remove the excess material of the inner spacer layer 410a without concern of increasing the size of any voids and/or seams that may have been formed in the inner spacer layer 410a. As a result, the surfaces of the source/drain recesses 305 from which source/drain regions may be epitaxially grown and/or on which source/regions may be deposited are free or substantially free of material of the inner spacer layer 410a, thereby allowing for flat and/or uncontaminated surfaces on which the source/drain regions will be formed. The resulting source/drain regions may have larger areas and be of higher quality than if the inner spacer layer 410a were deposited using other deposition techniques such as ALD, where etching and/or cleaning processes may be performed for a reduced time due to a higher risk of damage to inner spacers that may include defects such as seams and/or voids.

As shown in the cross-sectional plane B-B in FIG. 4C, the inner spacers 410b are formed in the cavities 405 between the ends of vertically adjacent nanostructure channels 315 in the source/drain recesses 305. The inner spacers 410b are included to reduce parasitic capacitance in the nanostructure transistors and to protect source/drain regions (that are subsequently formed in the source/drain recesses 305) from being etched in a nanosheet release operation to remove the sacrificial nanostructure layers 120 between the nanostructure channels 315, and/or from being damaged by gate metal deposited in place of removed sacrificial nanostructure layers 120. The fully merged (e.g., seam-free, void-free) structure of the inner spacers 410b provides enhanced protection against damage from etchants and/or extruded gate metal in comparison to inner spacers including seams and/or voids through which etchants and/or gate metal can pass to contact and damage source/drain regions.

As indicated above, FIGS. 4A-4C are provided as an example. Other examples may differ from what is described with regard to FIGS. 4A-4C.

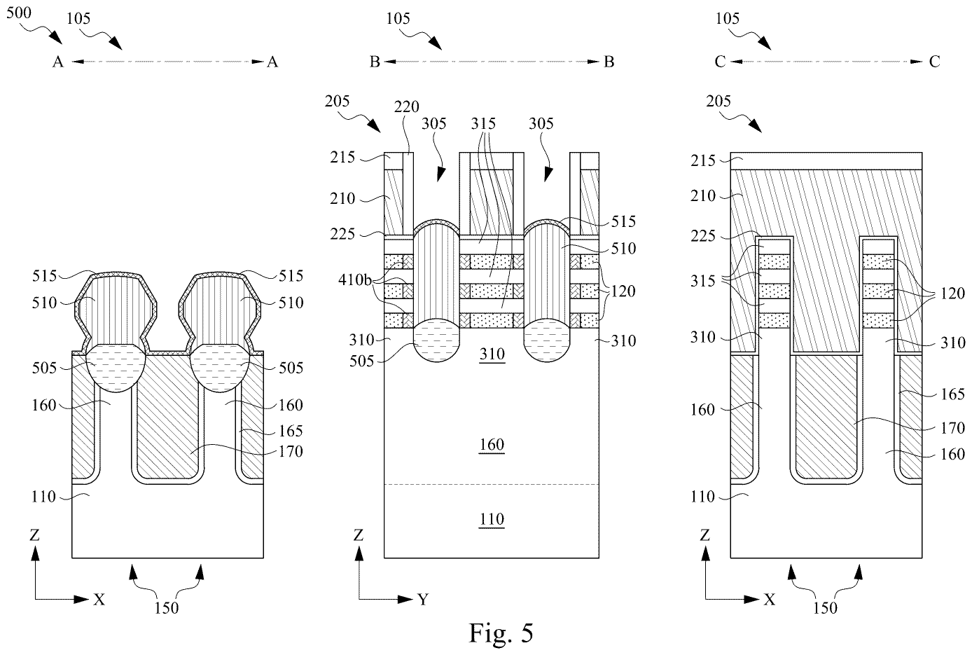

FIG. 5 is a diagram of an example implementation 500 of a source/drain region formation process described herein. The example implementation 500 includes an example of forming the source/drain regions of the nanostructure transistors of the semiconductor device 105. FIG. 5 is illustrated from a plurality of perspectives illustrated in FIG. 2, including the perspective of the cross-sectional plane A-A in FIG. 2, the perspective of the cross-sectional plane B-B in FIG. 2, and the perspective of the cross-sectional plane C-C in FIG. 2. In some implementations, the operations described in connection with the example implementation 500 are performed after the processes described in connection with FIGS. 1A-4C.

As shown in the cross-sectional plane A-A and the cross-sectional plane B-B in FIG. 5, the source/drain recesses 305 are filled with one or more layers to form the source/drain regions in the source/drain recesses 305. For example, a deposition tool may be used to deposit a buffer region 505 at the bottom of a source/drain recess 305, and a deposition tool may deposit a source/drain region 510 on the buffer region 505 in the source/drain recess 305. In some implementations, a deposition tool is used to deposit a capping layer 515 on the source/drain regions 510 in the source/drain recess 305.

A buffer region 505 may include silicon (Si), silicon doped with boron (SiB) or another dopant, and/or another material. A buffer region 505 may be included between a source/drain region 510 and the mesa regions 310 adjacent to the buffer region 505 to reduce, minimize, and/or prevent dopant migration and/or current leakage from the source/drain region 510 into the adjacent mesa region 310, which might otherwise cause short channel effects in the semiconductor device 105. Accordingly, the buffer region 505 may increase the performance of the semiconductor device 105 and/or increase yield of the semiconductor device 105.

A source/drain region 510 may refer to a source or a drain, individually or collectively dependent upon the context. Source/drain regions 510 may be included on opposing sides of a dummy gate structure 205 such that the nanostructure channels 315 under the dummy gate structure 205 extend between, and are electrically coupled to, source/drain regions 510. The source/drain regions 510 each include silicon (Si) with one or more dopants, such as a p-type material (e.g., boron (B) or germanium (Ge), among other examples), an n-type material (e.g., phosphorous (P) or arsenic (As), among other examples), and/or another type of dopant. Accordingly, the semiconductor device 105 may include p-type metal-oxide semiconductor (PMOS) nanostructure transistors that include p-type source/drain regions 510, n-type metal-oxide semiconductor (NMOS) nanostructure transistors that include n-type source/drain regions 510, and/or other types of nanostructure transistors.

One or more layers of a source/drain region 510 may be epitaxially grown, deposited (e.g., using CVD, PVD, ALD), and/or may be formed using one or more other deposition techniques. For example, a deposition tool may epitaxially grow a first layer of a source/drain region 510 (referred to as an L1) over an associated buffer region 505 (which may be referred to as an L0), and may epitaxially grow a second layer of the source/drain region 510 (referred to as an L2, an L2-1, and/or an L2-2) over the first layer. The first layer may include a lightly doped silicon (e.g., doped with boron (B), phosphorous (P), and/or another dopant), and may be included as shielding layer to reduce short channel effects in the semiconductor device 105 and to reduce dopant extrusion or migration into the nanostructure channels 315. The second layer may include a highly doped silicon or highly doped silicon germanium. The second layer may be included to provide a compressive stress in the source/drain regions 510 to reduce boron loss.

A capping layer 515 may include silicon, silicon germanium, doped silicon, doped silicon germanium, and/or another material. The capping layer 515 may be included to reduce dopant diffusion and to protect an underlying source/drain region 510 in semiconductor processing operations for the semiconductor device 105 prior to contact formation. Moreover, the capping layer 515 may contribute to metal-semiconductor (e.g., silicide) alloy formation.

As indicated above, FIG. 5 is provided as an example. Other examples may differ from what is described with regard to FIG. 5.

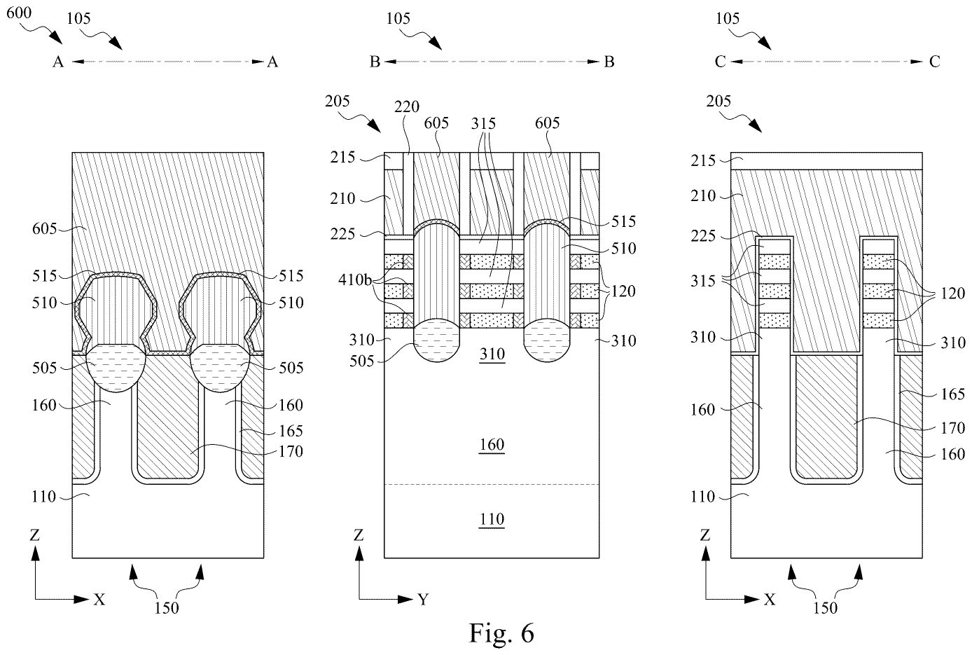

FIG. 6 is a diagram of an example implementation 600 of an interlayer dielectric (ILD) formation process described herein. FIG. 6 is illustrated from a plurality of perspectives illustrated in FIG. 2, including the perspective of the cross-sectional plane A-A in FIG. 2, the perspective of the cross-sectional plane B-B in FIG. 2, and the perspective of the cross-sectional plane C-C in FIG. 2. In some implementations, the operations described in connection with the example implementation 500 are performed after the processes described in connection with FIGS. 1A-5.

As shown in the cross-sectional plane A-A and the cross-sectional plane B-B in FIG. 6, a dielectric layer 605 is formed over the source/drain regions 510. The dielectric layer 605 (which may be referred to as an ILD layer) fills in areas between the dummy gate structures 205. The dielectric layer 605 is formed to reduce the likelihood of and/or prevent damage to the source/drain regions 510 during a replacement gate process to replace the dummy gate structures 205. The dielectric layer 605 may be referred to as an ILD zero (ILDO) layer or another ILD layer. In some implementations, the dielectric layer 605 is deposited using an ALD and/or CVD process (e.g., thermal ALD, PEALD, and/or plasma-enhanced chemical vapor deposition (PECVD)) that, unlike the flowable deposition process used to deposit the inner spacer layer 410a, may result in the formation of voids and/or seams in the dielectric layer 605.

In some implementations, a contact etch stop layer (CESL) is conformally deposited (e.g., by a deposition tool) over the source/drain regions 510 prior to formation of the dielectric layer 605. Alternatively, the capping layer 515 may a CESL. The dielectric layer 605 is then formed on the CESL. The CESL may provide a mechanism to stop an etch process when forming contacts or vias for the source/drain regions 510. The CESL may be formed of a dielectric material having a different etch selectivity from adjacent layers or components. The CESL may include or may be a nitrogen containing material, a silicon containing material, and/or a carbon containing material. Furthermore, the CESL may include or may be silicon nitride (SiₓN_{y}), silicon carbon nitride (SiCN), carbon nitride (CN), silicon oxynitride (SiON), silicon carbon oxide (SiCO), or a combination thereof, among other examples. The CESL may be deposited using a deposition process, such as ALD, CVD, or another deposition technique.

As indicated above, FIG. 6 is provided as an example. Other examples may differ from what is described with regard to FIG. 6.

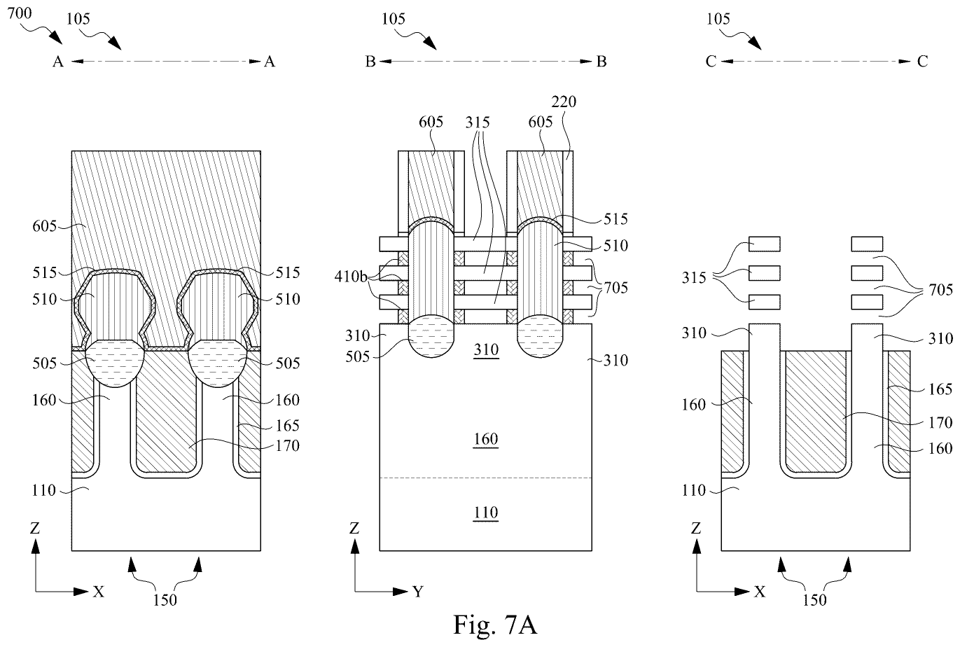

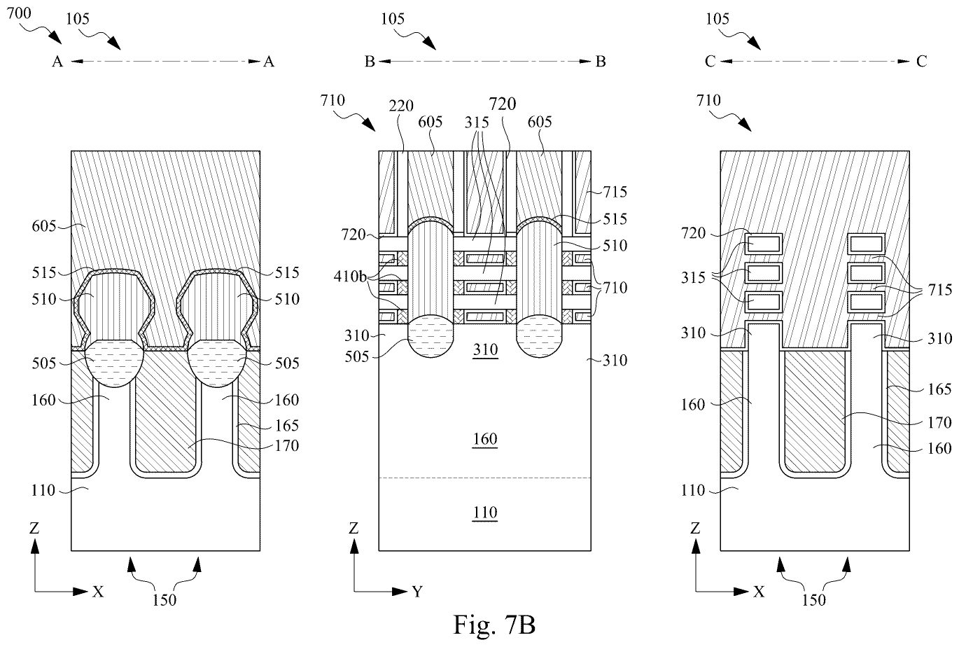

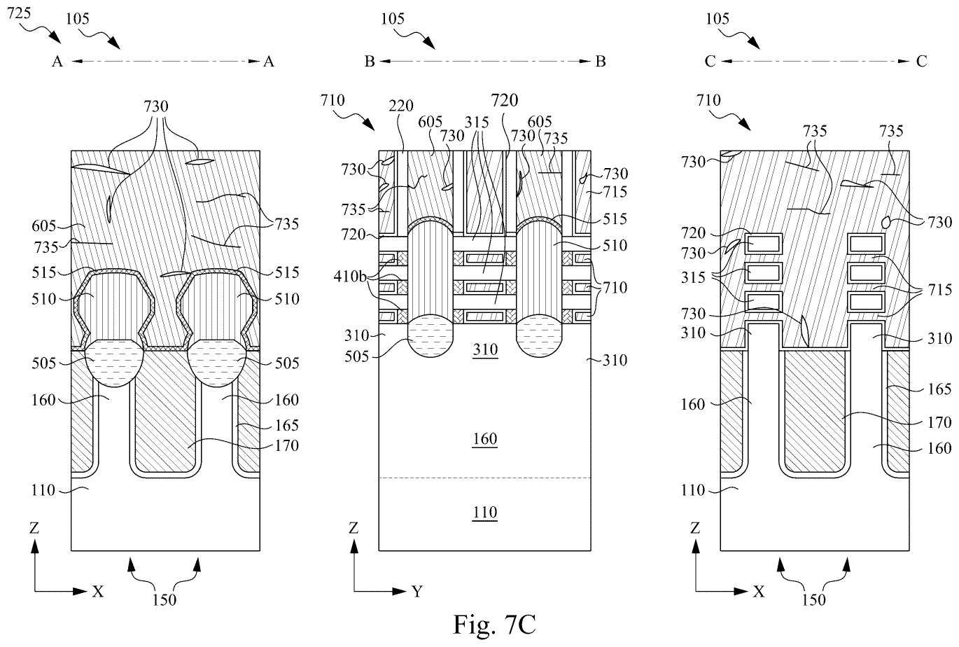

FIG. 7A7C are diagrams of an example implementation 700 of a replacement gate (RPG) process described herein. The example implementation 700 includes an example of a replacement gate process for replacing the dummy gate structures 205 with high-k/metal gate structures (e.g., the replacement gate structures) for the nanostructure transistors of the semiconductor device 105. FIGS. 7A-7C are each illustrated from a plurality of perspectives illustrated in FIG. 2, including the perspective of the cross-sectional plane A-A in FIG. 2, the perspective of the cross-sectional plane B-B in FIG. 2, and the perspective of the cross-sectional plane C-C in FIG. 2. In some implementations, the operations described in connection with the example implementation 700 are performed after the operations described in connection with FIGS. 1A-6.

As shown in the cross-sectional plane B-B and the cross-sectional plane C-C in FIG. 7A, the replacement gate process includes a dummy gate removal operation. The dummy gate removal operation includes removing the dummy gate structures 205 from the semiconductor device 105. The removal of the dummy gate structures 205 leaves behind openings (or recesses) between the dielectric layer 605, and provides access to the underlying sacrificial nanostructure layers 120. The dummy gate structures 205 may be removed in one or more etch operations. Such etch operations may include a plasma etch technique, a wet chemical etch technique, and/or another type of etch technique.

As further shown FIG. 7A, the replacement gate process includes a nanostructure release operation (e.g., an SiGe release operation). The nanostructure release operation is performed to remove the sacrificial nanostructure layers 120 (e.g., the silicon germanium layers). This results in openings 705 between the nanostructures channels 315 (e.g., the areas around the nanostructure channels 315). The sacrificial nanostructure layers 120 may be removed through the spaces that were previously occupied by the dummy gate structures 205. The nanostructure release operation may include the use of an etch tool to perform an etch operation to remove the sacrificial nanostructure layers 120 based on a difference in etch selectivity between the material of the sacrificial nanostructure layers 120 and the material of the nanostructure channels 315, and between the material of the sacrificial nanostructure layers 120 and the material of the inner spacers 410b. The inner spacers 410b may function as etch stop layers in the etch operation to protect the source/drain regions 510 from being etched. The fully merged (e.g., seam-free, void-free) structure of the inner spacers 410b provides enhanced protection against damage to source/drain regions 510 from etchants in comparison to inner spacers including seams and/or voids through which etchants can pass to contact and damage the source/drain regions 510.

As shown in the cross-sectional plane B-B and the cross-sectional plane C-C in FIG. 7B, the replacement gate operation includes forming gate structures (e.g., replacement gate structures) 710 in the openings 705 between the source/drain regions 510 and between the inner spacers 410b. In particular, the gate structures 710 fill the areas between and around the nanostructure channels 315 that were previously occupied by the sacrificial nanostructure layers 120 such that the gate structures 710 fully wrap around the nanostructure channels 315 and surround the nanostructure channels 315. This increases control of the nanostructure channel 315, increases drive current for the nanostructure transistor(s) of the semiconductor device 105, and/or reduces short channel effects (SCEs) for the nanostructure transistor(s) of the semiconductor device 105, among other examples. The gate structures 710 may also fill in the spaces that were previously occupied by the dummy gate structures 205. Portions of a gate structure 710 are formed in between pairs of nanostructure channels 315 in an alternating vertical arrangement. In other words, the semiconductor device 105 includes one or more vertical stacks of alternating nanostructure channels 315 and portions of a gate structure 710, as shown in FIG. 7B.

The gate structures 710 may each include a metal gate electrode 715. A metal gate electrode 715 may include one or more metal materials such as tungsten (W), cobalt (Co), ruthenium (Ru), and/or titanium (Ti), among other examples. Additionally and/or alternatively, the gate structures 710 may each include one or more work function metal layers for tuning the work function of the metal gate electrode 715. The fully merged (e.g., seam-free, void-free) structure of the inner spacers 410b provides enhanced protection against damage to source/drain regions 510 from deposited metal of metal gate electrodes 715, in comparison to inner spacers including seams and/or voids through which deposited metal can pass to contact and damage the source/drain regions 510.

Conformal high-k dielectric liners 720 of the gate structures 710 may be deposited onto the nanostructure channels 315 and on sidewalls of the inner spacers 410b prior to formation of the gate electrodes 715. The gate structures 710 may each include additional layers such as an interfacial layer, an adhesion layer, and/or a capping layer, among other examples. The high-k dielectric layers 720 each include one or more high-k dielectric materials, such as a silicon nitride (SiₓN_{y}), a hafnium oxide (HfOₓ), a lanthanum oxide (LaOₓ), and/or another suitable high-k dielectric material.

Some source/drain regions 510 and gate structures 710 may be shared between two or more nanoscale transistors of the semiconductor device 105. In these implementations, one or more source/drain regions 510 and a gate structure 710 may be connected or coupled to a plurality of nanostructure channels 315, as shown in the example in FIG. 7B. This enables the plurality of nanostructure channels 315 to be controlled by a single gate structure 710 and a pair of source/drain regions 510.

As shown in the example implementation 725 in FIG. 7C, the deposition of the dielectric layer 605 and the metal gate electrodes 715 using ALD and/or CVD techniques (e.g., thermal ALD, PEALD, and/or plasma-enhanced chemical vapor deposition (PECVD)) may result in the formation of voids 730 and/or seams 735 in the dielectric layer 605 and/or metal gate electrodes 715. In contrast, as explained in more detail in connection with FIG. 8B, a flowable deposition technique (e.g., FCVD) is used to deposit the inner spacer layer 410a. In the flowable deposition process, a ratio of a precursor material to a reactant by volume may be adjusted to control a flowability of inner spacer layer 410a so that a flowability is achieved that results in the inner spacer layer fully filling in the cavities 405, such that the inner spacer layer 410a is fully merged (e.g., seam-free and/or void-free) between nanostructure channels 315 over and/or under the cavities 405 and ends of sacrificial nanostructure layers 120 on sides of the cavities 405.

As indicated above, FIGS. 7A-7C are provided as an example. Other examples may differ from what is described with regard to FIGS. 7A-7C.

FIGS. 8A-8F are diagrams of an example implementation 800 of manufacturing a semiconductor device 105 described herein. The structure of the semiconductor device 105 in the example implementation 800 is similar to the structure of the semiconductor device 105 in the example implementations 100-700, with some noted differences. The cross-section B1-B1 is similar to the cross-section B-B, and is in a y-z plane (referred to as an x-cut) perpendicular to the cross-section A-A. Like the cross-section B-B, the cross-section B1-B1 is across the dummy gate structures 205 and along an underlying fin structure.

As shown in FIG. 8A, in the example implementation 800, a dummy gate structure 205 may include a gate electrode layer 210, a first hard mask layer 215a over and/or on the gate electrode layer 210, a second hard mask layer 215b over and/or on the first hard mask layer 215a, first spacer layers 220a on opposing sides of the gate electrode layer 210 and of the first and second hard mask layers 215a and 215b, and over and/or on the second hard mask layer 215b, second spacer layers 220b on the first spacer layers 220a, and a gate dielectric layer 225 under the gate electrode layer 210. The gate electrode layer 210 includes polycrystalline silicon (polysilicon or PO) or another material. The first hard mask layer 215a may include a first layer such as an oxide layer (e.g., a pad oxide layer that may include silicon dioxide (SiO₂) or another material) and the second hard mask layer 215b may include a nitride layer (e.g., a pad nitride layer that may include a silicon nitride such as Si₃N₄ or another material) formed over the first hard mask layer 215a. The first and second spacer layers 220a and 220b may include a silicon oxycarbide (SiOC), a nitrogen free SiOC, or another suitable material. The first and second spacer layers 220a and 220b may include different materials from each other, or the same materials as each other. The gate dielectric layer 225 may include a silicon oxide (e.g., SiOₓ such as SiO₂), a silicon nitride (e.g., SiₓN_{y} such as Si₃N₄), a high-k dielectric material, and/or another suitable material.

In the example implementation 800, the source/drain recesses 305 are formed between different stacks of sacrificial nanostructure layers 120 and nanostructure channels 315 in an alternating arrangement. The different stacks of sacrificial nanostructure layers 120 and nanostructure channels 315 are formed on respective mesa regions 310. The source/drain recesses 305 are formed in an etch operation, which may be performed using the etch tool and may be referred to as an SSD etch operation. In some implementations, the etch operation includes the use of a plasma etch technique, a wet chemical etch technique, and/or another type of etch technique.

The source/drain recesses 305 also extend into a portion of the fin portion 160 of the fin structure 150. This results in formation of the mesa regions 310 in the fin structure 150. The sidewalls of the portions of each source/drain recess 305 below the layer stack portions 155 of the fin structure 150 correspond to sidewalls of mesa regions 310.

The example implementation 800 includes an example of forming inner spacers between ends of the nanostructure channels 315 that are exposed in the source/drain recesses 305. As shown in the cross-sectional plane B1-B1 in FIG. 8A, the ends of the sacrificial nanostructure layers 120 that are exposed in the source/drain recesses 305 are laterally etched (e.g., in the x-direction that is approximately parallel to a length of the sacrificial nanostructure layers 120) in an etch operation, thereby forming cavities 405 between the ends of the sacrificial nanostructure layers 120 that are exposed in the source/drain recesses 305.

As shown in FIG. 8B, to ensure that material of the inner spacers 410b fully fills in the cavities 405 between and around the nanostructure channels 315, and adjacent the sacrificial nanostructure layers 120, a flowable deposition technique is used to deposit the material of the inner spacers 410b (e.g., the inner spacer layer 410a discussed in connection with FIG. 4B). The flowable deposition technique may include an FCVD technique in which a precursor 805 and a reactant 810 flow into the cavities 405 and around the nanostructure channels 315, and react to form the material of the inner spacers 410b. This may be referred to as the deposition aspect or step of the flowable CVD technique. The precursor 805 and the reactant 810 are easily able to flow into the cavities 405 between the nanostructure channels 315. This enables the material of the inner spacers 410b to fully fill in the cavities better than other deposition techniques such as ALD. The precursor 805 and the reactant 810 react to form a material that exhibits high conformal coating and gap filling properties.. This may be referred to as the conversion aspect or step of the flowable CVD technique.

In some implementations, a plurality of cycles of deposition steps and conversion steps are performed to form the material of the inner spacers 410b (e.g., the inner spacer layer 410a discussed in connection with FIG. 4B) in a seam-free manner. Each cycle may include a deposition step and a conversion step. In some implementations, two or more cycles are performed using the same process parameters, such as the same deposition flow rate of the precursor 805, the same deposition flow rate of the reactant 810, the same deposition temperature, the same deposition pressure, the same annealing temperature for the conversion step, and/or another common process parameter. In some implementations, two or more cycles are performed using different process parameters, such different deposition flow rates of the precursor 805, different deposition flow rates of the reactant 810, different deposition temperatures, different deposition pressures, and/or different annealing temperatures for the conversion step, among other examples.

To deposit the material of the inner spacers 410b, the flowable deposition technique may be used to perform a deposition operation, in which a deposition tool is used to flow the precursor 805 and the reactant 810 into the cavities 405 between the nanostructure channels 315 and adjacent to the sacrificial nanostructure layers 120. The semiconductor device 105 may be placed in a processing chamber of the deposition tool (e.g., a flowable CVD tool), and the deposition tool may be used to provide a gas flow containing the precursor 805 and a gas flow containing the reactant 810 into the processing chamber.

The flow rates of the gas flow containing the precursor 805 and the gas flow containing the reactant 810 may be selected so that the reaction between the precursor 805 and the reactant 810 occurs in the cavities 405 and on the surfaces of the nanostructure channels 315 and sacrificial nanostructure layers 120, as opposed to the reaction prematurely occurring in the processing chamber prior to reaching the surfaces of the nanostructure channels and sacrificial nanostructure layers 120. For example, the flow rates of the gas flow containing the precursor 805 and the gas flow containing the reactant 810 may be selected so that a ratio (e.g., by volume) of the dosage of the precursor 805 to the dosage of the reactant 810 is included in a range of approximately 1:0.15 to approximately 1:1.5 so that the reaction between the precursor 805 and the reactant 810 occurs in the cavities 405 and on the surfaces of the nanostructure channels 315 and of sacrificial nanostructure layers 120. However, other ranges and values for the ratio are within the scope of the present disclosure.

In some implementations, the pressure in the processing chamber may be maintained within a range of approximately 0.1 Torr to approximately 10 Torr to control the deposition rate of the precursor 805 and the reactant 810, as well as to achieve a high film uniformity and high conformality for the material of the inner spacers 410b. However, other values and ranges are within the scope of the present disclosure.

The pressure and/or the temperature in the processing chamber may also be controlled so that the reaction between the precursor 805 and the reactant 810 occurs in the cavities 405 and on the surfaces of the nanostructure channels 315 and of sacrificial nanostructure layers 120. For example, an annealing operation may be performed as part of the conversion step to promote thermal decomposition of the precursor 805 and/or to promote a reaction between the precursor 805 and the reactant 810. In some implementations, the annealing operation may be performed at a temperature that is included in a range of approximately 200 degrees Celsius to approximately 400 degrees Celsius to facilitate a reaction between the precursor 805 and the reactant 810. However, other values and ranges for the annealing temperature are within the scope of the present disclosure.

In some implementations, the material of the inner spacers 410b (and of the inner spacer layer 410a) is aluminum oxide (AIOₓ). In these implementations, the precursor 805 includes an aluminum oxide precursor and the reactant 810 includes a reactant that reacts with the aluminum oxide precursor to form the aluminum oxide of the inner spacers 410b. The reaction between the aluminum oxide precursor and the reactant may initially form aluminum oxide molecules that have a quantity of oxygen atoms in each molecule of aluminum oxide that is included in a range from 1 atom to 2 atoms. The reaction between the aluminum oxide precursor and the reactant may initially form aluminum oxide molecules such as aluminum(I) oxide (Al₂O) and/or aluminum(II) oxide (AIO). These aluminum oxide molecules may stabilize and deposit onto the nanostructure channels 315 and sacrificial nanostructure layers 120 as aluminum(III) oxide (Al₂O₃) or as aluminum oxide with aluminum and oxygen in other combinations or proportions (e.g., AlOₓ).

The precursor 805 (e.g., the aluminum oxide precursor) may include trimethylaluminum (TMA), triethylaluminum (TEA), dimethylethylaminealane (DMEAA), dimethylaluminum hydride (DMAH), tritertiarybutyl aluminum (TIBA), tri-isobutyl-aluminum (TIBA), trimethylamine alane (TMAA), triethylamine alane (TEAA), and/or another suitable aluminum-containing metalorganic precursor. For the aluminum oxide precursor, the reactant 810 may include an oxidizer such as oxygen (O₂), ozone (O₃), and/or water (H₂O), among other examples. In some implementations, the oxidizer includes an alcohol-based oxidizer, such as tert-Butanol ((CH₃)₃COH)), isomers of tert-Butanol (e.g., 1-butanol (C₄H₉OH), isobutanol ((CH₃)₂CHCH₂OH), and butan-2-ol (CH₃CH(OH)CH₂CH₃)) and/or another alcohol oxidant.

In some implementations, the material of the inner spacers 410b (and of the inner spacer layer 410a) is a silicon carbide (e.g., SiCₓ), a silicon oxycarbonnitride (e.g., SiOₓC_{y}N_{1-x-y}), or a silicon nitride (e.g., SiNₓ). In these implementations, the precursor 805 may include trisilylamine (TSA) ((SiH₃)₃N), di-isopropylaminosilane (DIPAS) (SiH₃N(C₃H₇)₂), or bis(diethylamino)silane (BDEAS) [SiH₂[N(CH₂CH₃)₂]₂). For the silicon carbide precursor, the silicon oxycarbonnitride precursor, or the silicon nitride precursor, the reactant 810 may include ammonia (NH₃), an oxidizer, and/or carbon dioxide (CO₂), among other examples. In some implementations, the oxidizer includes an alcohol-based oxidizer, such as tert-Butanol ((CH₃)₃COH)), isomers of tert-Butanol (e.g., 1-butanol (C₄H₉OH), isobutanol ((CH₃)₂CHCH₂OH), and butan-2-ol (CH3CH(OH)CH₂CH₃)) and/or another alcohol oxidant. The flowable deposition technique results in the inner spacers 410b being fully merged and seam-free between vertically adjacent nanostructure channels 315.

As shown in the cross-sectional plane B1-B1 in FIG. 8C, the source/drain recesses 305 are filled with one or more layers to form the source/drain regions 510 in the source/drain recesses 305. For example, a deposition tool may be used to deposit source/drain regions 510 in the source/drain recesses 305. In some implementations, as shown in the cross-sectional plane B1-B1 in FIG. 8D, a deposition tool is used to deposit a capping layer 515 on the source/drain regions 510.

Source/drain regions 510 may be included between different stacks of sacrificial nanostructure layers 120 and nanostructure channels 315 in the alternating arrangement. The different stacks of sacrificial nanostructure layers 120 and nanostructure channels 315 are formed on respective mesa regions 310. Portions of the source/drain regions 510 are disposed between the inner spacers 410b, such that ends of the inner spacers 410b facing the source/drain regions 510 contact the source/drain regions 510. The nanostructure channels 315 vertically adjacent to the inner spacers 410b contact and are electrically coupled to the source/drain regions 510.

One or more layers of a source/drain region 510 may be epitaxially grown, deposited (e.g., using CVD, PVD, ALD), and/or may be formed using one or more other deposition techniques. As noted herein, in forming the inner spacers 410b, the surfaces of the source/drain recesses 305 from which source/drain regions may be epitaxially grown and/or on which source/regions may be deposited may be sufficiently cleaned so that the surfaces are free or substantially free of material of the inner spacer layer 410a, thereby allowing for flat and/or uncontaminated surfaces on which the source/drain regions 510 can be formed.

The capping layers 515 may include silicon, silicon germanium, doped silicon, doped silicon germanium, and/or another material. The capping layers 515 may reduce dopant diffusion and protect underlying source/drain regions 510 in semiconductor processing operations for the semiconductor device 105 prior to contact formation.

As shown in the cross-sectional plane B1-B1 in FIG. 8D, the dielectric layer 605 is formed over the source/drain regions 510 and the capping layer 515. The first and second hard mask layers 215a and 215b, and upper portions of the first and second spacer layers 220a and 220b, may be removed using, for example, a planarization process such as chemical mechanical planarization (CMP). The removal exposes the gate electrode layers 210 of the dummy gate structures 205, which can be removed in one or more etch operations. Such etch operations may include a plasma etch technique, a wet chemical etch technique, and/or another type of etch technique. The removal of the gate electrode layers 210 leaves behind openings 815 (or recesses) between the dielectric layer 605, and provides access to the underlying sacrificial nanostructure layers 120. In some implementations, the dielectric layer 605 is recessed and cap layers 820 are formed on upper surfaces of the dielectric layer 605 between the first and second spacer layers 220a and 220b, and can include, for example, a silicon nitride (SiN), a boron nitride (BN), among other examples. A deposition tool may be used to deposit the cap layers 820 (e.g., using CVD, PVD, ALD, and/or another suitable deposition technique) followed by a planarization process.

As shown in the cross-sectional plane B1-B1 in FIG. 8E, following removal of the gate electrode layers 210 of the dummy gate structures 205, the replacement gate process includes the nanostructure release operation, where the sacrificial nanostructure layers 120 (e.g., the silicon germanium layers) are selectively removed with respect to the nanostructure channels 315 to result in the openings 705 between the nanostructures channels 315 (e.g., the areas around the nanostructure channels 315). The sacrificial nanostructure layers 120 may be removed through the spaces that were previously occupied by the dummy gate structures 205. The inner spacers 410b remain, and may function as etch stop layers in the etch operation to protect the source/drain regions 510 from being etched. The fully merged (e.g., seam-free, void-free) structure of the inner spacers 410b provides enhanced protection against damage to source/drain regions 510 from etchants during the nanostructure release operation.

As shown in the cross-sectional plane B1-B1 in FIG. 8F, the replacement gate operation includes forming gate structures (e.g., replacement gate structures) 710 in the openings 705 between the source/drain regions 510 and between the inner spacers 410b. The gate structures 710 fill the areas between and around the nanostructure channels 315 and between the inner spacers 410b that were previously occupied by the sacrificial nanostructure layers 120. The gate structures 710 may also fill in the spaces that were previously occupied by the dummy gate structures 205. Portions of a gate structure 710 are formed in between pairs of nanostructure channels 315 in an alternating vertical arrangement.

The gate structures 710 may each include a metal gate electrode 715, with the fully merged (e.g., seam-free, void-free) structure of the inner spacers 410b providing protection against damage to source/drain regions 510 from deposited metal of metal gate electrodes 715. Conformal high-k dielectric liners 720 of the gate structures 710 may be deposited onto the nanostructure channels 315 and on sidewalls of the inner spacers 410b prior to formation of the gate electrodes 715.

As indicated above, FIGS. 8A-8F are provided as an example. Other examples may differ from what is described with regard to FIGS. 8A-8F.

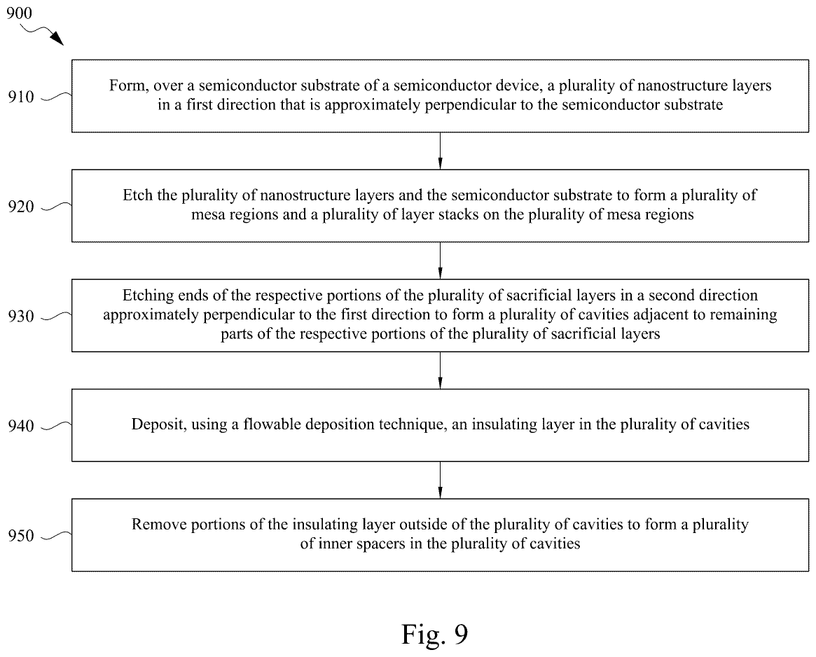

FIG. 9 is a flowchart of an example process 900 associated with forming a semiconductor device. In some implementations, one or more process blocks of FIG. 9 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 9, process 900 may include forming, over a semiconductor substrate of a semiconductor device, a plurality of nanostructure layers in a first direction that is approximately perpendicular to the semiconductor substrate (block 910). For example, one or more semiconductor processing tools may be used to form, over a semiconductor substrate (e.g., semiconductor substrate 110) of a semiconductor device (e.g., semiconductor device 105), a plurality of nanostructure layers in a first direction that is approximately perpendicular to the semiconductor substrate, as described herein. In some implementations, the plurality of nanostructure layers includes a plurality of sacrificial layers (e.g., sacrificial nanostructure layers 120) alternating with a plurality of channel layers (e.g., nanostructure channel layers 125).

As further shown in FIG. 9, process 900 may include etching the plurality of nanostructure layers and the semiconductor substrate to form a plurality of mesa regions and a plurality of layer stacks on the plurality of mesa regions (block 920). For example, one or more semiconductor processing tools may be used to etch the plurality of nanostructure layers and the semiconductor substrate to form a plurality of mesa regions (e.g., mesa regions 310) and a plurality of layer stacks (e.g., layer stack portions 155) on the plurality of mesa regions, as described herein. In some implementations, the plurality of layer stacks include respective portions of the plurality of sacrificial layers and respective portions of the plurality of channel layers.

As further shown in FIG. 9, process 900 may include etching ends of the respective portions of the plurality of sacrificial layers in a second direction approximately perpendicular to the first direction to form a plurality of cavities adjacent to remaining parts of the respective portions of the plurality of sacrificial layers (block 930). For example, one or more semiconductor processing tools may be used to etching ends of the respective portions of the plurality of sacrificial layers in a second direction approximately perpendicular to the first direction to form a plurality of cavities (e.g., cavities 405) adjacent to remaining parts of the respective portions of the plurality of sacrificial layers, as described herein.

As further shown in FIG. 9, process 900 may include depositing, using a flowable deposition technique, an insulating layer in the plurality of cavities (block 940). For example, one or more semiconductor processing tools may be used to deposit, using a flowable deposition technique, an insulating layer (e.g., inner spacer layer 410a) in the plurality of cavities, as described herein. In some implementations, the insulating layer fills the plurality of cavities.

As further shown in FIG. 9, process 900 may include removing portions of the insulating layer outside of the plurality of cavities to form a plurality of inner spacers in the plurality of cavities (block 950). For example, one or more semiconductor processing tools may be used to remove portions of the insulating layer outside of the plurality of cavities to form a plurality of inner spacers (e.g., inner spacers 410b) in the plurality of cavities, as described herein.

Process 900 may include additional implementations, such as any single implementation or any combination of implementations described below and/or in connection with one or more other processes described elsewhere herein.

In a first implementation, the flowable deposition technique includes a flowable chemical vapor deposition technique.

In a second implementation, alone or in combination with the first implementation, the insulating layer includes at least one of aluminum oxide (AlOₓ), silicon carbide (SiCₓ), silicon oxycarbonnitride (SiOₓC_{y}N_{1-x-y}), or silicon nitride (SiNₓ).

In a third implementation, alone or in combination with one or more of the first and second implementations, depositing the insulator layer includes reacting a precursor material (e.g., precursor 805) with a reactant (e.g., reactant 810) to form the insulating layer.

In a fourth implementation, alone or in combination with one or more of the first through third implementations, process 900 includes adjusting a ratio of the precursor material to the reactant by volume to control a flowability of the insulator layer.

Although FIG. 9 shows example blocks of process 900, in some implementations, process 900 includes additional blocks, fewer blocks, different blocks, or differently arranged blocks than those depicted in FIG. 9. Additionally, or alternatively, two or more of the blocks of process 900 may be performed in parallel.

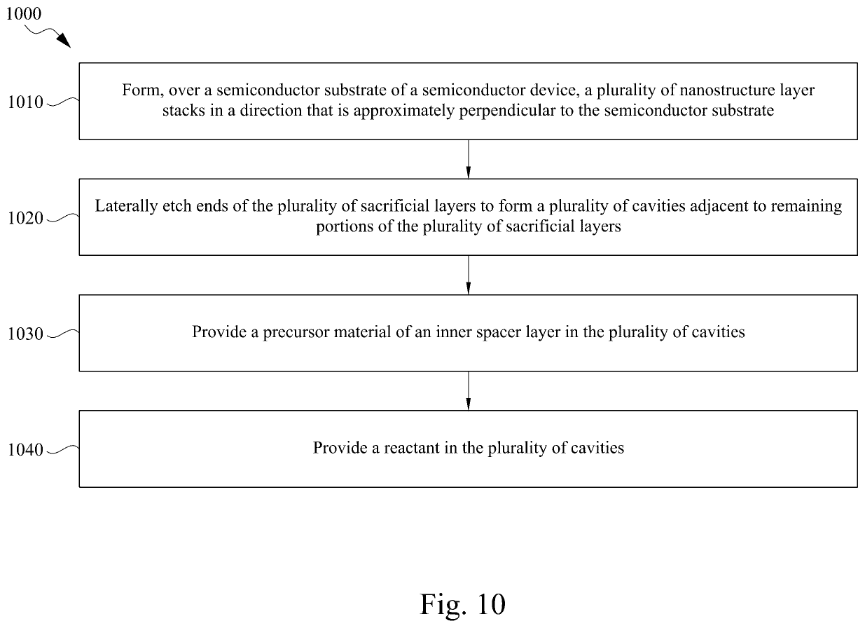

FIG. 10 is a flowchart of an example process 1000 associated with forming a semiconductor device. In some implementations, one or more process blocks of FIG. 10 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 10, process 1000 may include forming, over a semiconductor substrate of a semiconductor device, a plurality of nanostructure layer stacks in a direction that is approximately perpendicular to the semiconductor substrate (block 1010). For example, one or more semiconductor processing tools may be used to form, over a semiconductor substrate (e.g., semiconductor substrate 110) of a semiconductor device (e.g., semiconductor device 105), a plurality of nanostructure layer stacks (e.g., layer stack portions 155) in a direction that is approximately perpendicular to the semiconductor substrate, as described herein. In some implementations, the plurality of nanostructure layer stacks includes a plurality of sacrificial layers (e.g., sacrificial nanostructure layers 120) alternating with a plurality of channel layers (e.g., nanostructure channels 315).

As further shown in FIG. 10, process 1000 may include laterally etching ends of the plurality of sacrificial layers to form a plurality of cavities adjacent to remaining portions of the plurality of sacrificial layers (block 1020). For example, one or more semiconductor processing tools may be used to laterally etch ends of the plurality of sacrificial layers to form a plurality of cavities (e.g. cavities 405) adjacent to remaining portions of the plurality of sacrificial layers, as described herein. In some implementations, the ends of the plurality of sacrificial layers are selectively etched with respect to the plurality of channel layers.

As further shown in FIG. 10, process 1000 may include providing a precursor material of an inner spacer layer in the plurality of cavities (block 1030). For example, one or more semiconductor processing tools may be used to provide a precursor material (e.g., precursor 805) of an inner spacer layer (e.g., inner spacer layer 410a) in the plurality of cavities, as described herein. In some implementations, the precursor material of the inner spacer layer flows in the plurality of cavities at least one of over or under vertically adjacent channel layers of the plurality of channel layers.

As further shown in FIG. 10, process 1000 may include providing a reactant in the plurality of cavities (block 1040). For example, one or more semiconductor processing tools may be used to provide a reactant (e.g., reactant 810) in the plurality of cavities, as described herein. In some implementations, the reactant flows in the plurality of cavities at least one of over or under vertically adjacent channel layers of the plurality of channel layers. In some implementations, the precursor material and the reactant react to form the inner spacer layer in the plurality of cavities.

Process 1000 may include additional implementations, such as any single implementation or any combination of implementations described below and/or in connection with one or more other processes described elsewhere herein.

In a first implementation, the precursor material of the inner spacer layer includes an aluminum oxide (AlOₓ) precursor.

In a second implementation, alone or in combination with the first implementation, the aluminum oxide precursor includes at least one of trimethylaluminum (TMA), triethylaluminum (TEA), dimethylethylaminealane (DMEAA), dimethylaluminum hydride (DMAH), tritertiarybutyl aluminum (TTBA), tri-isobutyl-aluminum (TIBA), triimethylylamine alane (TMAA), or trimethylamine alane (TEAA).

In a third implementation, alone or in combination with one or more of the first and second implementations, the reactant includes an oxidizer.

In a fourth implementation, alone or in combination with one or more of the first through third implementations, the oxidizer includes at least one of oxygen (O₂), an alcohol, ozone (O₃), or water (H₂O).

In a fifth implementation, alone or in combination with one or more of the first through fourth implementations, the precursor material of the inner spacer layer includes one of a silicon carbide (SiCₓ) precursor, a silicon oxycarbonnitride (SiOₓC_{y}N_{1-x-y}) precursor, or a silicon nitride (SiNₓ) precursor.

In a sixth implementation, alone or in combination with one or more of the first through fifth implementations, at least one of the silicon carbide precursor, the silicon oxycarbonnitride precursor, or the silicon nitride precursor includes one of trisilylamine (TSA), di-isopropylaminosilane (DIPAS), or bis(diethylamino)silane (BDEAS).

In a seventh implementation, alone or in combination with one or more of the first through sixth implementations, the reactant includes at least one of ammonia (NH₃), an alcohol, or carbon dioxide (CO₂).

In an eighth implementation, alone or in combination with one or more of the first through seventh implementations, a ratio of the precursor material to the reactant by volume is included in a range of approximately 1:0.15 to approximately 1:1.5.

In a ninth implementation, alone or in combination with one or more of the first through eighth implementations, process 1000 includes removing portions of the inner spacer layer outside of the plurality of cavities to form a plurality of inner spacers (e.g., inner spacers 410b) in the plurality of cavities, and epitaxially growing one or more source/drain regions (e.g., source/drain regions 510) from the vertically adjacent channel layers of the plurality of channel layers.

Although FIG. 10 shows example blocks of process 1000, in some implementations, process 1000 includes additional blocks, fewer blocks, different blocks, or differently arranged blocks than those depicted in FIG. 10. Additionally, or alternatively, two or more of the blocks of process 1000 may be performed in parallel.

In this way, flowable low-k and ultra low-k dielectric materials may be used as materials for nanostructure transistor inner spacers to prevent the formation of inner spacer defects. A flowable deposition process (e.g., a flowable chemical vapor deposition (FCVD) process) may be used to deposit the flowable low-k and ultra low-k dielectric materials (e.g., aluminum oxide (AlOₓ), silicon carbide (SiCₓ), silicon oxycarbonnitride (SiOₓC_{y}N_{1-x-y}), silicon nitride (SiNₓ)) to avoid inner spacer defect formation. Ratios of precursors to reactants used in the flowable deposition process may be tuned to increase flowability in order to prevent generation of seams and/or voids in the inner spacers. If defect formation is avoided, processes to trim and/or clean nanostructure channel surfaces prior to epitaxial growth of source/drain regions may be performed for a requisite amount of time without concern that defects will be enlarged. As a result, inner spacer material may be sufficiently removed from the surfaces from and/or on which source/drain regions will be formed, leading to larger areas of higher quality and uncontaminated epitaxial source/drain regions. Moreover, due to the lack of defects in inner spacers formed using the techniques described herein, the inner spacers may provide increased protection from parasitic capacitance between gates and source/drain regions in nanostructure transistors. The void-and/or seam-free inner spacers may also prevent etchants and/or deposited metal from a replacement metal gate operation from contacting and/or damaging source/drain regions, thereby increasing performance and yield of resulting nanostructure transistors in comparison to when other spacer materials and deposition processes are used.

As described in greater detail above, some implementations described herein provide a method. The method includes forming, over a semiconductor substrate of a semiconductor device, a plurality of nanostructure layers in a first direction that is approximately perpendicular to the semiconductor substrate, where the plurality of nanostructure layers includes a plurality of sacrificial layers alternating with a plurality of channel layers. The method includes etching the plurality of nanostructure layers and the semiconductor substrate to form a plurality of mesa regions and a plurality of layer stacks on the plurality of mesa regions, where the plurality of layer stacks include respective portions of the plurality of sacrificial layers and respective portions of the plurality of channel layers. The method includes etching ends of the respective portions of the plurality of sacrificial layers in a second direction approximately perpendicular to the first direction to form a plurality of cavities adjacent to remaining parts of the respective portions of the plurality of sacrificial layers. The method includes depositing, using a flowable deposition technique, an insulating layer in the plurality of cavities, where the insulating layer fills the plurality of cavities. The method includes removing portions of the insulating layer outside of the plurality of cavities to form a plurality of inner spacers in the plurality of cavities.

As described in greater detail above, some implementations described herein provide a method. The method includes forming, over a semiconductor substrate of a semiconductor device, a plurality of nanostructure layer stacks in a direction that is approximately perpendicular to the semiconductor substrate, where the plurality of nanostructure layer stacks includes a plurality of sacrificial layers alternating with a plurality of channel layers. The method includes laterally etching ends of the plurality of sacrificial layers to form a plurality of cavities adjacent to remaining portions of the plurality of sacrificial layers, where the ends of the plurality of sacrificial layers are selectively etched with respect to the plurality of channel layers. The method includes providing a precursor material of an inner spacer layer in the plurality of cavities, where the precursor material of the inner spacer layer flows in the plurality of cavities at least one of over or under vertically adjacent channel layers of the plurality of channel layers.

The method includes providing a reactant in the plurality of cavities, where the reactant flows in the plurality of cavities at least one of over or under vertically adjacent channel layers of the plurality of channel layers, and where the precursor material and the reactant react to form the inner spacer layer in the plurality of cavities ..

As described in greater detail above, some implementations described herein provide a semiconductor device. The semiconductor device includes a first plurality of nanostructure channels arranged in a first direction in the semiconductor device. The semiconductor device includes a second plurality of nanostructure channels arranged in the first direction, where the second plurality of nanostructure channels are adjacent to the first plurality of nanostructure channels in a second direction that is approximately perpendicular to the first direction,. The semiconductor device includes a first gate structure wrapping around each of the first plurality of nanostructure channels. The semiconductor device includes a second gate structure wrapping around each of the second plurality of nanostructure channels. The semiconductor device includes a first plurality of inner spacers on ends of the first gate structure and disposed at least one of over or under adjacent nanostructure channels of the first plurality of nanostructure channels. The semiconductor device includes a second plurality of inner spacers on ends of the second gate structure and disposed at least one of over or under adjacent nanostructure channels of the second plurality of nanostructure channels, where the first plurality of inner spacers are fully merged between the adjacent nanostructure channels of the first plurality of nanostructure channels, and where the second plurality of inner spacers are fully merged between the adjacent nanostructure channels of the second plurality of nanostructure channels.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming, over a semiconductor substrate of a semiconductor device, a plurality of nanostructure layers in a first direction that is approximately perpendicular to the semiconductor substrate,
wherein the plurality of nanostructure layers comprises a plurality of sacrificial layers alternating with a plurality of channel layers;
etching the plurality of nanostructure layers and the semiconductor substrate to form a plurality of mesa regions and a plurality of layer stacks on the plurality of mesa regions,
wherein the plurality of layer stacks comprise respective portions of the plurality of sacrificial layers and respective portions of the plurality of channel layers;
etching ends of the respective portions of the plurality of sacrificial layers in a second direction approximately perpendicular to the first direction to form a plurality of cavities adjacent to remaining parts of the respective portions of the plurality of sacrificial layers;
depositing, using a flowable deposition technique, an insulating layer in the plurality of cavities,
wherein the insulating layer fills the plurality of cavities; and
removing portions of the insulating layer outside of the plurality of cavities to form a plurality of inner spacers in the plurality of cavities.

2. The method of claim 1, wherein the flowable deposition technique comprises a flowable chemical vapor deposition technique.

3. The method of claim 1, wherein the insulating layer comprises at least one of:
aluminum oxide (AlOₓ),
silicon carbide (SiCₓ), silicon oxycarbonnitride (SiOₓC_{y}N_{1-x-y}), or
silicon nitride (SiNₓ).

4. The method of claim 1, wherein depositing the insulator layer comprises reacting a precursor material with a reactant to form the insulating layer.

5. The method of claim 4, further comprising adjusting a ratio of the precursor material to the reactant by volume to control a flowability of the insulator layer.

6. A method, comprising:
forming, over a semiconductor substrate of a semiconductor device, a plurality of nanostructure layer stacks in a direction that is approximately perpendicular to the semiconductor substrate,
wherein the plurality of nanostructure layer stacks comprises a plurality of sacrificial layers alternating with a plurality of channel layers;
laterally etching ends of the plurality of sacrificial layers to form a plurality of cavities adjacent to remaining portions of the plurality of sacrificial layers,
wherein the ends of the plurality of sacrificial layers are selectively etched with respect to the plurality of channel layers;
providing a precursor material of an inner spacer layer in the plurality of cavities,
wherein the precursor material of the inner spacer layer flows in the plurality of cavities at least one of over or under vertically adjacent channel layers of the plurality of channel layers; and
providing a reactant in the plurality of cavities,
wherein the reactant flows in the plurality of cavities at least one of over or under the vertically adjacent channel layers of the plurality of channel layers, and
wherein the precursor material and the reactant react to form the inner spacer layer in the plurality of cavities.

7. The method of claim 6, wherein the precursor material of the inner spacer layer comprises an aluminum oxide (AlOₓ) precursor.

8. The method of claim 7, wherein the aluminum oxide precursor comprises at least one of:
trimethylaluminum (TMA),
triethylaluminum (TEA),
dimethylethylaminealane (DMEAA),
dimethylaluminum hydride (DMAH),
tritertiarybutyl aluminum (TTBA),
tri-isobutyl-aluminum (TIBA),
trimethylamine alane (TMAA), or
tryethylamine alane (TEAA).

9. The method of claim 7, wherein the reactant comprises an oxidizer.

10. The method of claim 9, wherein the oxidizer comprises at least one of:
oxygen (O₂),
an alcohol,
ozone (O₃), or
water (H₂O).

11. The method of claim 6, wherein the precursor material of the inner spacer layer comprises one of a silicon carbide (SiCₓ) precursor, a silicon oxycarbonnitride (SiOₓC_{y}N_{1-x-y}) precursor, or a silicon nitride (SiNₓ) precursor.

12. The method of claim 11, wherein at least one of the silicon carbide precursor, the silicon oxycarbonnitride precursor, or the silicon nitride precursor comprises one of:
trisilylamine (TSA),
di-isopropylaminosilane (DIPAS), or
bis(diethylamino)silane (BDEAS).

13. The method of claim 12, wherein the reactant comprises at least one of ammonia (NH₃), an alcohol, or carbon dioxide (CO₂).

14. The method of claim 6, wherein a ratio of the precursor material to the reactant by volume is included in a range of approximately 1:0.15 to approximately 1:1.5.

15. The method of claim 6, further comprising:
removing portions of the inner spacer layer outside of the plurality of cavities to form a plurality of inner spacers in the plurality of cavities; and
epitaxially growing one or more source/drain regions from the vertically adjacent channel layers of the plurality of channel layers.

16. A semiconductor device, comprising:
a first plurality of nanostructure channels arranged in a first direction in the semiconductor device;
a second plurality of nanostructure channels arranged in the first direction,
wherein the second plurality of nanostructure channels are adjacent to the first plurality of nanostructure channels in a second direction that is approximately perpendicular to the first direction,
a first gate structure wrapping around each of the first plurality of nanostructure channels;
a second gate structure wrapping around each of the second plurality of nanostructure channels;
a first plurality of inner spacers on ends of the first gate structure and disposed at least one of over or under adjacent nanostructure channels of the first plurality of nanostructure channels; and
a second plurality of inner spacers on ends of the second gate structure and disposed at least one of over or under adjacent nanostructure channels of the second plurality of nanostructure channels,
wherein the first plurality of inner spacers are fully merged between the adjacent nanostructure channels of the first plurality of nanostructure channels, and
wherein the second plurality of inner spacers are fully merged between the adjacent nanostructure channels of the second plurality of nanostructure channels.

17. The semiconductor device of claim 16, wherein the first plurality of inner spacers and the second plurality of inner spacers comprise at least one of aluminum oxide (AlOₓ) and silicon carbide (SiCₓ).

18. The semiconductor device of claim 16, further comprising a source/drain region between the first plurality of nanostructure channels and the second plurality of nanostructure channels,
wherein the first plurality of inner spacers are disposed and fully merged between the source/drain region and the ends of the first gate structure, and
wherein the second plurality of inner spacers are disposed and fully merged between the source/drain region and the ends of the second gate structure.

19. The semiconductor device of claim 16, wherein the first plurality of inner spacers and the second plurality of inner spacers are formed of a dielectric material having a dielectric constant less than approximately 3.9.

20. The semiconductor device of claim 16, wherein the first plurality of inner spacers and the second plurality of inner spacers are formed of a dielectric material having a dielectric constant less than approximately 2.4.
